(19) United States
(12) Patent Application Publication
(10) Pub. No.: US 2024/0206202 A1
(43) Pub. Date: Jun. 20, 2024

(54) LIGHT DETECTION APPARATUS, LIGHT DETECTION SYSTEM, ELECTRONIC EQUIPMENT, AND MOBILE BODY

(71) Applicant: SONY SEMICONDUCTOR SOLUTIONS CORPORATION, KANAGAWA (JP)

(72) Inventor: KOHEI FUKUSHIMA, KANAGAWA (JP)

(21) Appl. No.: 18/554,065

(22) PCT Filed: Feb. 17, 2022
(86) PCT No.: PCT/JP2022/006355

§ 371 Date: Oct. 5, 2023

(30) Foreign Application Priority Data
Apr. 20, 2021 (JP) 2021-070934

(51) Int. Cl. H10K 39/32; G01S 7/481

(52) U.S. Cl. CPC H10K 39/32; G01S 7/4816

(57) ABSTRACT

Provided is a light detection apparatus with high functionality. The light detection apparatus includes: an effective region that extends along a first plane and includes a first photoelectric conversion unit; and a peripheral region provided adjacent to the effective region along the first surface. The first photoelectric conversion unit detects light in a first wavelength range to perform photoelectric conversion. The peripheral region includes a structural body spaced apart from and adjacent to the first photoelectric conversion unit. The structural body has the substantially same configuration as an entirety of the first photoelectric conversion unit or a portion of the first photoelectric conversion unit.

### TECHNICAL FIELD

The present disclosure relates to a light detection apparatus, a light detection system, electronic equipment, and a mobile body each including a photoelectric conversion element that performs photoelectric conversion.

### BACKGROUND ART

So far, the Applicant has made a proposal for an imaging element that makes it possible to enhance an optical characteristic, and an imaging apparatus including the imaging element (refer to PTL 1, for example).

### CITATION LIST

### Patent Literature

PTL 1: Japanese Unexamined Patent Application Publication No. 2019-16667

### SUMMARY OF THE INVENTION

Meanwhile, further enhancement in performance has been desired for a light detection apparatus used in an imaging apparatus.

Accordingly, it is desired to provide a light detection apparatus having high performance.

A light detection apparatus according to an embodiment of the present disclosure includes: an effective region that extends along a first plane and includes a first photoelectric conversion unit; and a peripheral region provided adjacent to the effective region along the first plane. The first photoelectric conversion unit detects light in a first wavelength range to perform photoelectric conversion. The peripheral region includes a structural body spaced apart from and adjacent to the first photoelectric conversion unit. The structural body has a substantially same configuration as an entirety of the first photoelectric conversion unit or a portion of the first photoelectric conversion unit.

In the light detection apparatus according to the embodiment of the present disclosure, the structural body is provided in the peripheral region adjacent to the effective region including the first photoelectric conversion unit. The structural body is spaced apart from and adjacent to the first photoelectric conversion unit, and has the substantially same configuration as the entirety of the first photoelectric conversion unit or a portion of the first photoelectric conversion unit. This suppresses generation of residue near an edge surface of the effective region, in patterning the first photoelectric conversion unit by, for example, dry etching.

### BRIEF DESCRIPTION OF DRAWINGS

FIG. 1A is a schematic configuration diagram illustrating an exemplary solid-state imaging apparatus according to a first embodiment of the present disclosure.

FIG. 1B is an explanatory diagram schematically illustrating a configuration example of a pixel unit and a peripheral unit illustrated in FIG. 1A.

FIG. 2A is a vertical cross-sectional view illustrating an exemplary schematic configuration of an imaging element applied to the pixel unit illustrated in FIG. 1A.

FIG. 2B is a horizontal cross-sectional view illustrating an exemplary schematic configuration of the imaging element applied to the pixel unit illustrated in FIG. 1A.

FIG. 2C is another horizontal cross-sectional view illustrating an exemplary schematic configuration of the imaging element applied to the pixel unit illustrated in FIG. 1A.

FIG. 3 is a vertical enlarged cross-sectional view illustrating, in an enlarged manner, the vicinity of a boundary between the pixel unit and the peripheral unit, in the solid-state imaging apparatus illustrated in FIG. 1.

FIG. 4 is a circuit diagram illustrating an exemplary read-out circuit of an iTOF sensor unit illustrated in FIG. 2A.

FIG. 5 is a circuit diagram illustrating an exemplary read-out circuit of an organic photoelectric conversion unit illustrated in FIG. 2A.

FIG. 6 is a cross-sectional view illustrating a process of a manufacturing method of the solid-state imaging apparatus illustrated in FIG. 1.

FIG. 7A is a cross-sectional view illustrating a process subsequent to FIG. 6.

FIG. 7B is a plan view illustrating a process subsequent to FIG. 6.

FIG. 8 is a cross-sectional view illustrating a process subsequent to FIGS. 7A and 7B.

FIG. 9 is a cross-sectional view illustrating a process subsequent to FIG. 8.

FIG. 10 is a vertical enlarged cross-sectional view illustrating, in an enlarged manner, the vicinity of a boundary between a pixel unit and a peripheral unit, in a solid-state imaging apparatus as a reference example.

FIG. 11 is a cross-sectional view illustrating a process of a manufacturing method of the solid-state imaging apparatus illustrated in FIG. 10.

FIG. 12 is a cross-sectional view illustrating a process subsequent to FIG. 11.

FIG. 13A is a vertical cross-sectional view illustrating an exemplary schematic configuration of an imaging element as a first modification example applicable to the solid-state imaging apparatus illustrated in FIG. 1A.

FIG. 13B is a horizontal cross-sectional view illustrating an exemplary schematic configuration of the imaging element as the first modification example illustrated in FIG. 13A.

FIG. 14A is a vertical cross-sectional view illustrating an exemplary schematic configuration of an imaging element as a second modification example applicable to the solid-state imaging apparatus illustrated in FIG. 1A.

FIG. 14B is a horizontal cross-sectional view illustrating an exemplary schematic configuration of the imaging element as the second modification example illustrated in FIG. 14A.

FIG. 15 is a vertical cross-sectional view illustrating an exemplary schematic configuration of a pixel unit as a third modification example applicable to the solid-state imaging apparatus illustrated in FIG. 1A.

FIG. 16A is a schematic diagram illustrating an exemplary overall configuration of a light detection system according to a second embodiment of the present disclosure.

FIG. 16B is a schematic diagram illustrating an exemplary circuit configuration of the light detection system illustrated in FIG. 16A.

FIG. 17 is a schematic diagram illustrating an exemplary overall configuration of electronic equipment.

FIG. 18 is a block diagram depicting an example of a schematic configuration of an in-vivo information acquisition system.

FIG. 19 is a view depicting an example of a schematic configuration of an endoscopic surgery system.

FIG. 20 is a block diagram depicting an example of a functional configuration of a camera head and a camera control unit (CCU).

FIG. 21 is a block diagram depicting an example of schematic configuration of a vehicle control system.

FIG. 22 is a diagram of assistance in explaining an example of installation positions of an outside-vehicle information detecting section and an imaging section.

FIG. 23 is an explanatory diagram schematically illustrating a configuration example of a pixel unit and its peripheral unit in a solid-state imaging apparatus as a third modification example of the present disclosure.

FIG. 24 is an explanatory diagram schematically illustrating a configuration example of a pixel unit and its peripheral unit in a solid-state imaging apparatus as a fourth modification example of the present disclosure.

FIG. 25 is an explanatory diagram schematically illustrating a configuration example of a pixel unit and its peripheral unit in a solid-state imaging apparatus as a fifth modification example of the present disclosure.

FIG. 26 is an explanatory diagram schematically illustrating a configuration example of a pixel unit and its peripheral unit in a solid-state imaging apparatus as a sixth modification example of the present disclosure.

FIG. 27 is an explanatory diagram schematically illustrating a configuration example of a pixel unit and its peripheral unit in a solid-state imaging apparatus as a seventh modification example of the present disclosure.

### MODES FOR CARRYING OUT THE INVENTION

In the following, some embodiments of the present disclosure are described in detail with reference to the drawings. It is to be noted that the description is given in the following order.

### 1. First Embodiment

An exemplary solid-state imaging apparatus in which structural bodies are arranged in a peripheral region surrounding an effective region including vertical spectroscopic imaging elements each including a first photoelectric conversion unit and a second photoelectric conversion unit

### 2. First Modification Example

### 3. Second Modification Example

### 4. Third Modification Example

### 5. Second Embodiment

An exemplary light detection system including a light-emitting apparatus and a light detection apparatus

### 6. Exemplary Application to Electronic Equipment

### 7. Application Example to In-vivo Information Acquisition System

### 8. Application Example to Endoscopic Surgery System

### 9. Exemplary Application to Mobile Body

### 10. Other Modification Examples

### 1. FIRST EMBODIMENT

### [Configuration of Solid-State Imaging Apparatus 1]

### (Exemplary Overall Configuration)

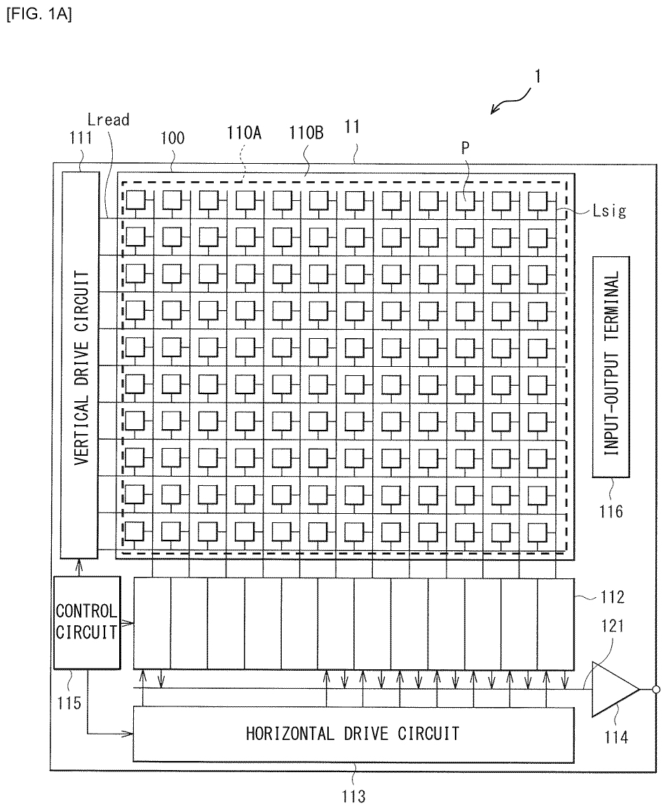

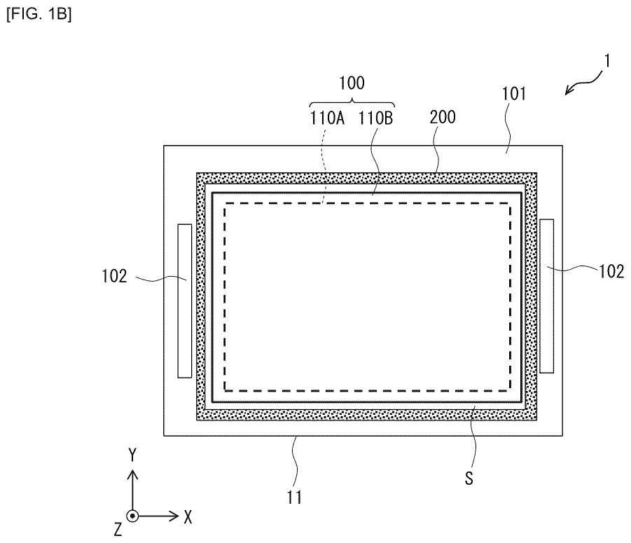

FIG. 1A illustrates an exemplary overall configuration of a solid-state imaging apparatus 1 according to a first embodiment of the present disclosure. FIG. 1B is a schematic diagram illustrating a pixel unit 100 and a periphery of the pixel unit 100 in an enlarged manner. The solid-state imaging apparatus 1 is, for example, a complementary metal oxide semiconductor (CMOS) image sensor. The solid-state imaging apparatus 1 receives entering light (image light) from an object through an optical lens system, for example. The solid-state imaging apparatus 1 converts the entering light focused on an imaging plane into an electric signal on a pixel-by-pixel basis, and outputs the electric signal as a pixel signal. The solid-state imaging apparatus 1 includes the pixel unit 100 and a peripheral unit 101 as a peripheral region adjacent to the pixel unit 100 on, for example, a semiconductor substrate 11. The pixel unit 100 includes an effective region 110A and an optical black (OB) region 110B. The OB region 110B surrounds the effective region 110A. The peripheral unit 101 is provided to surround the pixel unit 100, for example. As illustrated in FIG. 1A, the peripheral unit 101 includes a vertical drive circuit 111, column signal processing circuits 112, a horizontal drive circuit 113, an output circuit 114, a control circuit 115, and an input-output terminal 116, for example.

It is to be noted that the solid-state imaging apparatus 1 is a specific example corresponding to a “light detection apparatus” of the present disclosure.

As illustrated in FIG. 1A, the effective region 110A of the pixel unit 100 includes multiple pixels P arranged in a two-dimensional matrix, for example. The effective region 110A includes, for example, multiple pixel rows and multiple pixel columns. The multiple pixel rows each include multiple pixels P arranged in a horizontal direction (a lateral direction of the drawing). The multiple pixel columns each include multiple pixels P arranged in a vertical direction (a longitudinal direction of the drawing). In the pixel unit 100, for example, one pixel drive line Lread (a row selection line and a reset control line) is provided for each pixel row, and one vertical signal line Lsig is provided for each pixel column. The pixel drive line Lread transmits a drive signal to read a signal from each pixel P. Ends of the multiple pixel drive lines Lread are coupled to multiple output terminals of the vertical drive circuit 111 corresponding to the respective pixel rows.

The OB region 110B is a part that outputs optical black as a reference of a black level.

In the peripheral unit 101, a structural body 200 is provided. Moreover, in a portion of the peripheral unit 101, a contact region 102 (FIG. 1B) is provided. To the contact region 102, a contact layer 57 (described later) and a lead-out wiring 58 (described later) are coupled.

The vertical drive circuit 111 includes a shift register and an address decoder, for example. The vertical drive circuit 111 is a pixel drive unit that drives each pixel P in the pixel unit 100 on a pixel-row basis, for example. A signal outputted from each pixel P of a pixel row selectively scanned by the vertical drive circuit 111 is supplied to the column signal processing circuit 112 through the corresponding vertical signal line Lsig.

The column signal processing circuit 112 includes an amplifier and a horizontal selection switch that are provided for each vertical signal line Lsig, for example.

The horizontal drive circuit 113 includes a shift register and an address decoder, for example. The horizontal drive circuit 113 drives the horizontal selection switches of the column signal processing circuits 112 in sequence while scanning the horizontal selection switches. Owing to the selective scanning by the horizontal drive circuit 113, the signal of each pixel P transmitted through each of the multiple vertical signal lines Lsig is sequentially outputted to the horizontal signal line 121, and transmitted through the horizontal signal line 121 to the outside of the semiconductor substrate 11.

The output circuit 114 conducts signal processing on the signals sequentially supplied from the respective column signal processing circuits 112 through the horizontal signal line 121, and outputs the resultant signals. For example, in some cases, the output circuit 114 performs only buffering. In other cases, the output circuit 114 performs a black level adjustment, column variation correction, and a variety of digital signal processing.

A circuit portion including the vertical drive circuit 111, the column signal processing circuits 112, the horizontal drive circuit 113, the horizontal signal line 121, and the output circuit 114 may be formed directly on the semiconductor substrate 11, or may be provided on an external control IC. Alternatively, the circuit portion may be formed on another substrate coupled with a cable, for example.

The control circuit 115 receives, for example, a clock supplied from the outside of the semiconductor substrate 11, and data that gives a command for an operation mode. Moreover, the control circuit 115 outputs data such as internal information regarding the pixels P as imaging elements. The control circuit 115 further includes a timing generator that generates various timing signals. On the basis of the various timing signals generated by the timing generator, the control circuit 115 makes a driving control of peripheral circuitry including the vertical drive circuit 111, the column signal processing circuits 112, and the horizontal drive circuit 113.

The input-output terminal 116 exchanges signals with an external device.

### (Exemplary Cross-sectional Configuration of Pixel P)

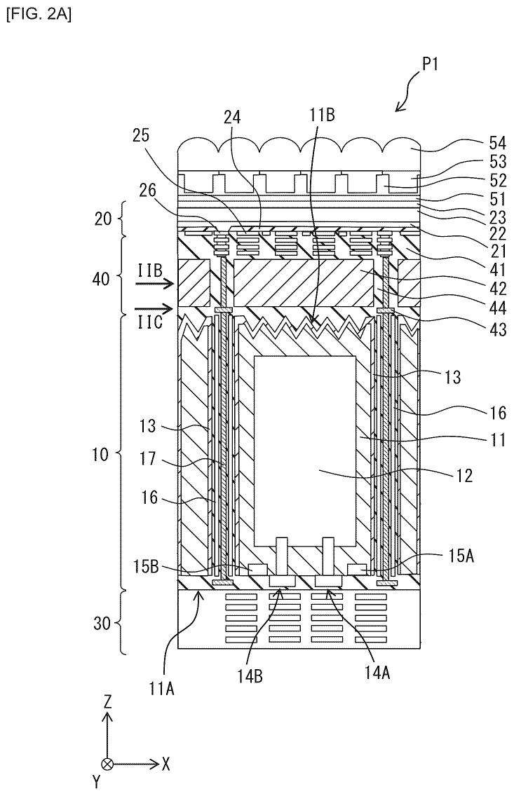

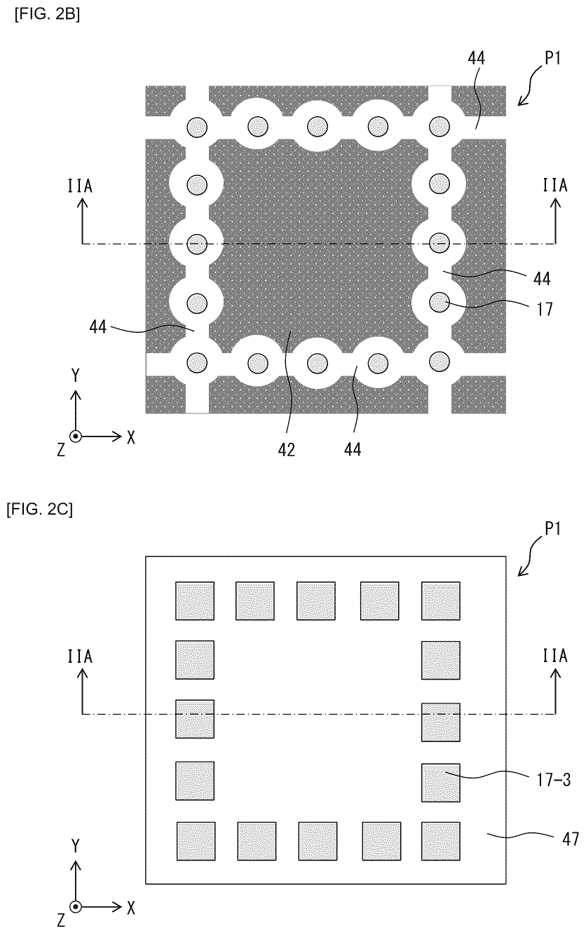

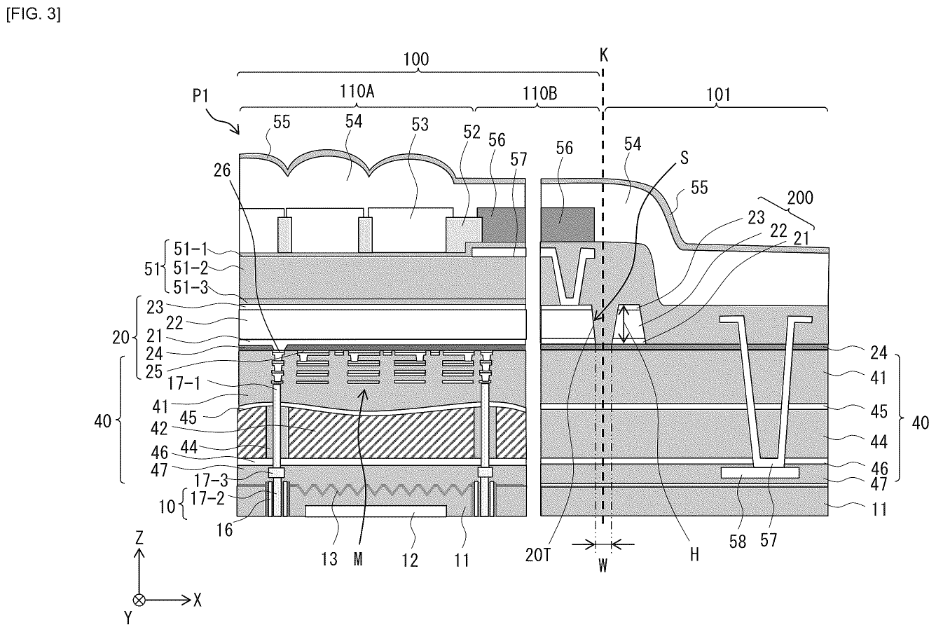

FIG. 2A schematically illustrates an exemplary vertical cross-sectional configuration, along a thickness direction, of one pixel P1 of the multiple pixels P arranged in a matrix in the effective region 110A of the pixel unit 100. FIG. 2B schematically illustrates an exemplary horizontal cross-sectional configuration along a lamination plane direction orthogonal to the thickness direction at a height position in a Z-axis direction indicated by an arrow IIB in FIG. 2A. Further, FIG. 2C schematically illustrates an exemplary horizontal cross-sectional configuration along the lamination plane direction orthogonal to the thickness direction at a height position in the Z-axis direction indicated by an arrow IIC in FIG. 2A. It is to be noted that FIG. 2A corresponds to a cross-section in an arrowed direction taken along lines IIA-IIA illustrated in each of FIGS. 2B and 2C. Furthermore, FIG. 3 is an enlarged cross-sectional view illustrating, in an enlarged manner, a vertical cross-sectional configuration near a boundary K between the pixel unit 100 and the peripheral unit 101, in the solid-state imaging apparatus 1. In FIGS. 2A to 2C and FIG. 3, the thickness direction (lamination direction) of the pixel P1 is the Z-axis direction, and planar directions parallel to the lamination plane orthogonal to the Z-axis direction are an X-axis direction and a Y-axis direction. It is to be noted that the X-axis direction, the Y-axis direction, and the Z-axis direction are orthogonal to each other.

As illustrated in FIG. 2A, the pixel P1 is a so-called vertical spectroscopic imaging element having a structure in which one second photoelectric conversion unit 10 and one first photoelectric conversion unit 20 are stacked in the Z-axis direction or the thickness direction, for example. The pixel P1 as an imaging element is a specific example corresponding to a “light detection element” of the present disclosure. The pixel P1 further includes an intermediate layer 40 and a multilayer wiring layer 30. The intermediate layer 40 is provided between the second photoelectric conversion unit 10 and the first photoelectric conversion unit 20. The multilayer wiring layer 30 is provided on opposite side to the first photoelectric conversion unit 20 as seen from the second photoelectric conversion unit 10. Further, on light-entering side opposite to the second photoelectric conversion unit 10 as seen from the first photoelectric conversion unit 20, a sealing film 51, a low refractive index layer 52, multiple color filters 53, and a lens layer 54 are stacked in order along the Z-axis direction from a position close to the first photoelectric conversion unit 20, for example. The lens layer 54 includes on-chip lenses (OCL) provided corresponding to the respective color filters 53. It is to be noted that the sealing film 51 and the low refractive index layer 52 may each be common to the multiple pixels P. The sealing film 51 has a stacked structure including transparent insulating films 51-1 to 51-3 such as AlOx. Further, an antireflection film 55 (illustrated in FIG. 3A described later) may be provided to cover the lens layer 54. A black filter 56 may be provided in the peripheral unit 101. The multiple color filters 53 may each include, for example, a color filter that transmits mainly red light, a color filter that transmits mainly green light, and a color filter that transmits mainly blue light. It is to be noted that each pixel P1 of the present embodiment includes red, green, and blue color filters 53, and the first photoelectric conversion unit 20 receives red light, green light, and blue light to obtain a colored visible light image.

### (Second Photoelectric Conversion Unit 10)

The second photoelectric conversion unit 10 is an indirect TOF (hereinafter referred to as iTOF) sensor that acquires a distance image (distance information) on the basis of Time-of-Flight (TOF), for example. The second photoelectric conversion unit 10 includes, for example, the semiconductor substrate 11, a photoelectric conversion region 12, a fixed charge layer 13, a pair of transfer transistors (TGs) 14A and 14B, charge-voltage converters (FDs) 15A and 15B as floating diffusion regions, an inter-pixel region light shielding wall 16, and a through-electrode 17.

The semiconductor substrate 11 is, for example, an n-type silicon (Si) substrate having a front face 11A and a rear face 11B. The semiconductor substrate 11 has a p-well in a predetermined region. The front face 11A faces the multilayer wiring layer 30. The rear face 11B is a face that faces the intermediate layer 40. The rear face 11B preferably has a micro-irregular structure (RIG structure). One reason for this is that light having a wavelength in an infrared light range as a second wavelength range (e.g., a wavelength of 880 nm to 1040 nm, both inclusive) that enters the semiconductor substrate 11 is effectively confined inside the semiconductor substrate 11. It is to be noted that the front face 11A may also have a similar micro-irregular structure.

The photoelectric conversion region 12 is, for example, a photoelectric conversion element including a positive intrinsic negative (PIN) photodiode (PD). The photoelectric conversion region 12 includes a pn junction formed in a predetermined region of the semiconductor substrate 11. The photoelectric conversion region 12 detects and receives light having a wavelength particularly in the infrared light range, within the light from the object. The photoelectric conversion region 12 generates electric charge corresponding to the amount of received light through photoelectric conversion and accumulates the electric charge.

The fixed charge layer 13 is provided to cover the rear face 11B of the semiconductor substrate 11, for example. The fixed charge layer 13 has negative fixed charge, for example, to suppress the occurrence of dark currents caused by an interface state of the rear face 11B that serves as a light-receiving face of the semiconductor substrate 11. By an electrical field induced by the fixed charge layer 13, a hole accumulation layer is formed in the vicinity of the rear face 11B of the semiconductor substrate 11. The hole accumulation layer suppresses the generation of electrons from the rear face 11B. It is to be noted that the fixed charge layer 13 includes a portion extending in the Z-axis direction between the inter-pixel region light shielding wall 16 and the photoelectric conversion region 12. The fixed charge layer 13 is preferably formed using an insulating material. Specific examples of a constituting material of the fixed charge layer 13 include hafnium oxide (HfOx), aluminum oxide (AlOx), zirconium oxide (ZrOx), tantalum oxide (TaOx), titanium oxide (TiOx), lanthanum oxide (LaOx), praseodymium oxide (PrOx), cerium oxide (CeOx), neodymium oxide (NdOx), promethium oxide (PmOx), samarium oxide (SmOx), europium oxide (EuOx), gadolinium oxide (GdOx), terbium oxide (TbOx), dysprosium oxide (DyOx), holmium oxide (HoOx), thulium oxide (TmOx), ytterbium oxide (YbOx), lutetium oxide (LuOx), yttrium oxide (YOx), hafnium nitride (HfNx), aluminum nitride (AlNx), hafnium oxynitride (HfOxNy), and aluminum oxynitride (AlOxNy).

The pair of the TGs 14A and 14B each extend in the Z-axis direction from the front face 11A to the photoelectric conversion region 12, for example. The TG 14A and the TG 14B transfer the electric charge accumulated in the photoelectric conversion region 12 to the pair of the FDs 15A and 15B in response to a drive signal applied.

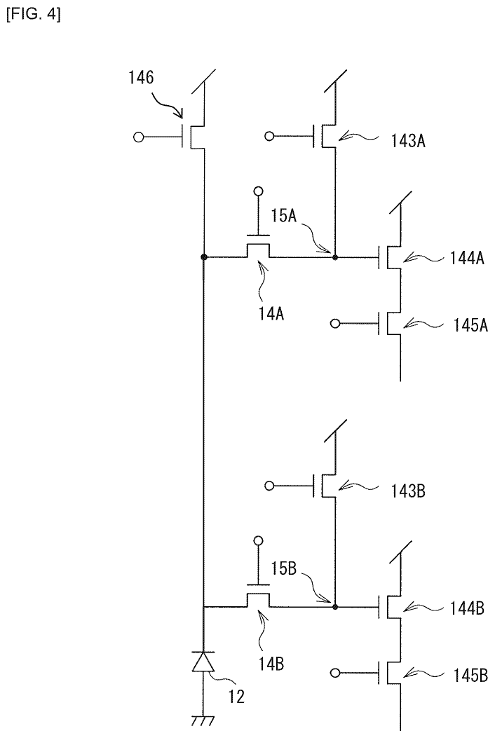

The pair of the FDs 15A and 15B are floating diffusion regions that convert the electric charge transferred from the photoelectric conversion region 12 through the TGs 14A and 14B into electric signals (e.g., voltage signals) and output the signals. To the FDs 15A and 15B, as illustrated in FIG. 4 described later, reset transistors (RSTs) 143A and 143B are respectively coupled. Moreover, to the FDs 15A and 15B, as illustrated in FIG. 4 described later, the vertical signal line Lsig (FIG. 1A) is coupled through amplification transistors (AMPs) 144A and 144B and selection transistors (SELs) 145A and 145B.

The inter-pixel region light shielding wall 16 includes, for example, a portion extending along an XZ plane and a portion extending along a YZ plane. The inter-pixel region light shielding wall 16 is provided to surround the photoelectric conversion region 12 of each pixel P. Moreover, the inter-pixel region light shielding wall 16 may be provided to surround the through-electrode 17. Thus, it is possible to suppress unwanted light from entering obliquely the photoelectric conversion region 12 between adjacent pixels P, leading to prevention of color mixture.

The inter-pixel region light shielding wall 16 includes, for example, a material containing at least one of a metal simple substance, a metal alloy, a metal nitride, or a metal silicide having a light-shielding property. More specifically, examples of a constituent material of the inter-pixel region light shielding wall 16 include Al (aluminum), Cu (copper), Co (cobalt), W (tungsten), Ti (titanium), Ta (tantalum), Ni (nickel), Mo (molybdenum), Cr (chromium), Ir (iridium), platinum-iridium, TiN (titanium nitride), and tungsten-silicon compounds. It is to be noted that the constituent material of the inter-pixel region light shielding wall 16 is not limited to a metal material, but the inter-pixel region light shielding wall 16 may be formed using graphite. In addition, the material of the inter-pixel region light shielding wall 16 is not limited to an electrically conductive material, but the inter-pixel region light shielding wall 16 may include a non-electrically conductive material having light shielding properties such as an organic material. Further, between the inter-pixel region light shielding wall 16 and the through-electrode 17, an insulating layer may be provided. The insulating layer includes an insulating material such as SiOx (silicon oxide) or aluminum oxide. Alternatively, between the inter-pixel region light shielding wall 16 and the through-electrode 17, a cavity may be provided to insulate the inter-pixel region light shielding wall 16 and the through-electrode 17 from each other. It is to be noted that in a case where the inter-pixel region light shielding wall 16 includes a non-electrically conductive material, no insulating layer may be provided. Furthermore, outside the inter-pixel region light shielding wall 16, that is, between the inter-pixel region light shielding wall 16 and the fixed charge layer 13, an insulating layer may be provided. The insulating layer includes an insulating material such as SiOx (silicon oxide) or aluminum oxide. Alternatively, between the inter-pixel region light shielding wall 16 and the fixed charge layer 13, a cavity may be provided to insulate the inter-pixel region light shielding wall 16 and the fixed charge layer 13 from each other.

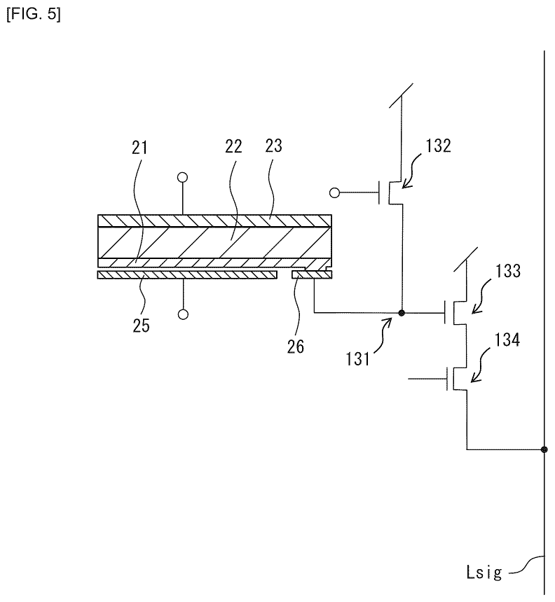

The through-electrode 17 is, for example, a coupling member that electrically couples a read-out electrode 26 of the first photoelectric conversion unit 20 to an FD 131 and an AMP 133 (refer to FIG. 5 described later). The read-out electrode 26 is provided on the rear face 11B side of the semiconductor substrate 11. The FD 131 and the AMP 133 are provided on the front face 11A of the semiconductor substrate 11. The through-electrode 17 makes, for example, a transmission path that transmits signal charge generated in the first photoelectric conversion unit 20 and transmits a voltage that drives a charge accumulation electrode 25. For example, the through-electrode 17 may be provided to extend in the Z-axis direction from the read-out electrode 26 of the first photoelectric conversion unit 20 to the multilayer wiring layer 30 through the semiconductor substrate 11. The through-electrode 17 is configured to favorably transfer the signal charge generated in the first photoelectric conversion unit 20 provided on the side on which the rear face 11B of the semiconductor substrate 11 is disposed, to side on which the front face 11A of the semiconductor substrate 11 is disposed. As illustrated in FIGS. 2B and 3B, the through-electrode 17 penetrates in the Z-axis direction an inside of an inter-pixel region light shielding wall 44. That is, around the through-electrode 17, the fixed charge layer 13 and the inter-pixel region light shielding wall 44 (described later) are provided. The inter-pixel region light shielding wall 44 has electrical insulating properties. Thus, the through-electrode 17 and the p-well region of the semiconductor substrate 11 are electrically insulated from each other. Furthermore, the through-electrode 17 includes a first through-electrode section 17-1 and a second through-electrode section 17-2. The first through-electrode section 17-1 penetrates the inside of the inter-pixel region light shielding wall 44 in the Z-axis direction. The second through-electrode section 17-2 penetrates an inside of the inter-pixel region light shielding wall 16 in the Z-axis direction. The first through-electrode section 17-1 and the second through-electrode section 17-2 are coupled, for example, through a coupling electrode section 17-3. A maximum dimension of the coupling electrode section 17-3 in an XY in-plane direction is, for example, greater than both a maximum dimension of the first through-electrode section 17-1 in the XY in-plane direction and a maximum dimension of the second through-electrode section 17-2 in the in-plane direction.

The through-electrode 17 may be formed using, for example, one kind, or two or more kinds of metal materials such as aluminum (Al), tungsten (W), titanium (Ti), cobalt (Co), platinum (Pt), palladium (Pd), copper (Cu), hafnium (Hf), and tantalum (Ta), in addition to an impurity-doped silicon material such as phosphorus-doped amorphous silicon (PDAS).

### (Multilayer Wiring Layer 30)

The multilayer wiring layer 30 illustrated in FIG. 2A includes, for example, the RSTs 143A and 143B, the AMPs 144A and 144B, the SELs 145A and 145B, and the like that constitute a read-out circuit together with the TGs 14A and 14B.

### (Intermediate Layer 40)

The intermediate layer 40 may include, for example, an insulating layer 41 and an optical filter 42 embedded in the insulating layer 41. The intermediate layer 40 may further include the inter-pixel region light shielding wall 44 as a first light shielding member that blocks at least light having a wavelength in the infrared light range (e.g., a wavelength of 880 nm to 1040 nm, both inclusive) as the second wavelength range. The insulating layer 41 includes, for example, a single-layer film including one of inorganic insulating materials such as silicon oxide (SiOx), silicon nitride (SiNx), and silicon oxynitride (SiON), or a laminated film including two or more of these materials. Further, as a material constituting the insulating layer 41, an organic insulating material may be used. Examples of the organic insulating material include polymethyl methacrylate (PMMA), polyvinyl phenol (PVP), polyvinyl alcohol (PVA), polyimide, polycarbonate (PC), polyethylene terephthalate (PET), polystyrene, N-2(aminoethyl)3-aminopropyl trimethoxysilane (AEAPTMS), 3-mercaptopropyl trimethoxysilane (MPTMS), tetraethoxysilane (TEOS), and octadecyl trichlorosilane (OTS). Further, in the insulating layer 41, a wiring layer M is embedded. The wiring layer M includes various wirings including a transparent electrically conductive material. The wiring layer M is coupled to the charge accumulation electrode 25 to be described later. The inter-pixel region light shielding wall 44 includes a single-layer film including a material that mainly blocks light in the infrared light range, for example, one of inorganic insulating materials such as silicon oxide (SiOx), silicon nitride (SiNx), and silicon oxynitride (SiON), or a laminated film including two or more of these materials. The inter-pixel region light shielding wall 44 may be formed integrally with the insulating layer 41. The inter-pixel region light shielding wall 44 surrounds the optical filter 42 along the XY plane to overlap with the optical filter 42 at least partially in the XY plane orthogonal to the thickness direction (Z-axis direction). As with the inter-pixel region light shielding wall 16, the inter-pixel region light shielding wall 44 suppresses unwanted light from entering obliquely the photoelectric conversion region 12 between the adjacent pixels P1, leading to the prevention of color mixture.

The optical filter 42 has a transmission band in the infrared light range where the photoelectric conversion region 12 performs photoelectric conversion. In other words, the optical filter 42 transmits light having a wavelength in the infrared light range, i.e., infrared light, more easily than light having a wavelength in a visible light range (e.g., a wavelength of 400 nm to 700 nm, both inclusive) as a first wavelength range, i.e., visible light. Specifically, the optical filter 42 may include, for example, an organic material, and is configured to absorb at least a portion of light having a wavelength in the visible light range while selectively transmitting light in the infrared light range. The optical filter 42 includes an organic material such as a phthalocyanine derivative, for example. In addition, the multiple optical filters 42 provided in the pixel unit 100 may have substantially the same shape and substantially the same size.

As illustrated in FIG. 3, a SiN layer 45 may be provided on a rear face of the optical filter 42, that is, a face of the optical filter 42 opposed to the first photoelectric conversion unit 20. In addition, a SiN layer 46 may be provided on a front face of the optical filter 42, that is, a face of the optical filter 42 opposed to the second photoelectric conversion unit 10. Further, an insulating layer 47 including, for example, SiOx may be provided between the semiconductor substrate 11 and the SiN layer 46.

As illustrated in FIG. 3, the intermediate layer 40 preferably extends along the XY plane not only in the pixel unit 100 but also in the peripheral unit 101. As illustrated in FIG. 3, in the contact region 102 (FIG. 1B) within the peripheral unit 101, the contact layer 57 and the lead-out wiring 58 are coupled. The contact layer 57 and the lead-out wiring 58 are each embedded in the intermediate layer 40.

### (First Photoelectric Conversion Unit 20)

As illustrated in FIG. 3, the first photoelectric conversion unit 20 includes, for example, the read-out electrode 26, a semiconductor layer 21, a photoelectric conversion layer 22, and an upper electrode 23 that are stacked in this order from a position close to the second photoelectric conversion unit 10. The first photoelectric conversion unit 20 further includes an insulating layer 24 and the charge accumulation electrode 25. The insulating layer 24 is provided below the semiconductor layer 21. The charge accumulation electrode 25 is provided opposed to the semiconductor layer 21, with the insulating layer 24 interposed therebetween. The charge accumulation electrode 25 and the read-out electrode 26 are spaced apart from each other, and are provided, for example, at the same layer level. The read-out electrode 26 is in contact with an upper end of the through-electrode 17. Further, as illustrated in FIG. 3, for example, the first photoelectric conversion unit 20 is coupled to the lead-out wiring 58 through the contact layer 57 in the peripheral unit 101. It is to be noted that each of the upper electrode 23, the photoelectric conversion layer 22, and the semiconductor layer 21 may be common to some pixels P1 of the multiple pixels P1 in the pixel unit 100. Alternatively, each of the upper electrode 23, the photoelectric conversion layer 22, and the semiconductor layer 21 may be common to all the multiple pixels P in the pixel unit 100. The same applies to modification examples described below.

It is to be noted that another organic layer may be provided between the photoelectric conversion layer 22 and the semiconductor layer 21, and between the photoelectric conversion layer 22 and the upper electrode 23.

The read-out electrode 26, the upper electrode 23, and the charge accumulation electrode 25 include a light-transmissive electrically conductive film. Examples of a constituent material of the light-transmissive electrically conductive film include ITO (indium-tin-oxide), a tin oxide (SnOx)-based material to which a dopant is added, or a zinc oxide-based material obtained by adding a dopant to zinc oxide (ZnO). Examples of the zinc oxide-based material include aluminum zinc oxide (AZO) to which aluminum (Al) is added as a dopant, gallium zinc oxide (GZO) to which gallium (Ga) is added, and indium zinc oxide (IZO) to which indium (In) is added. In addition, as the constituent material of the read-out electrode 26, the upper electrode 23, and the charge accumulation electrode 25, CuI, InSbO₄, ZnMgO, CuInO₂, MgIN₂O₄, CdO, ZnSnO₃, TiO₂, or the like may be used. Further, a spinel-type oxide or an oxide having a YbFe₂O₄ structure may be used.

The photoelectric conversion layer 22 converts light energy into electric energy, and includes two or more kinds of organic materials that function as a p-type semiconductor and an n-type semiconductor, for example. A p-type semiconductor relatively functions as an electron donor. An n-type semiconductor relatively functions as an n-type semiconductor that functions as an electron acceptor. The photoelectric conversion layer 22 has a bulk hetero-junction structure in the layer. The bulk hetero-junction structure is a p/n junction interface formed by mixing of a p-type semiconductor and an n-type semiconductor. Excitons generated upon light absorption are separated into electrons and holes at the p/n junction interface. It is to be noted that the photoelectric conversion layer 22 is not limited to a case where the photoelectric conversion layer 22 includes an organic material, but the photoelectric conversion layer 22 may be devoid of organic materials.

In addition to the p-type semiconductor and the n-type semiconductor, the photoelectric conversion layer 22 may further include three kinds of so-called dye materials that performs photoelectric conversion of light in a predetermined wavelength range while transmitting light in other wavelength ranges. The p-type semiconductor, the n-type semiconductor, and the dye materials preferably have absorption maximum wavelengths different from each other. This makes it possible to absorb wavelengths in the visible light range over a wide range.

The photoelectric conversion layer 22 may be formed, for example, by mixing the various organic semiconductor materials described above and using a spin coating technique. Alternatively, the photoelectric conversion layer 22 may be formed using, for example, a vacuum deposition method, a printing technique, or the like.

As the material constituting the semiconductor layer 21, a material is preferably used that has a large bandgap value (for example, a bandgap value of 3.0 eV or greater) and a higher mobility than the constituting material of the photoelectric conversion layer 22. Specific examples thereof include: oxide semiconductor materials such as IGZO; transition-metal dichalcogenide; silicon carbide; diamond; graphene; a carbon nanotube; and organic semiconductor materials such as condensed polycyclic hydrocarbon compounds and condensed heterocyclic compounds.

The charge accumulation electrode 25 forms a kind of capacitor together with the insulating layer 24 and the semiconductor layer 21, and accumulates electric charge generated in the photoelectric conversion layer 22 in a portion of the semiconductor layer 21, for example, a region portion of the semiconductor layer 21 that corresponds to the charge accumulation electrode 25, with the insulating layer 24 in between. In the present embodiment, for example, one charge accumulation electrode 25 is provided corresponding to each of one color filter 53 and one on-chip lens. The charge accumulation electrode 25 is coupled to, for example, the vertical drive circuit 111.

The insulating layer 24 may include, for example, an inorganic insulating material and an organic insulating material similar to those of the insulating layer 41.

The first photoelectric conversion unit 20 detects all or a part of the wavelengths in the visible light range. Further, it is desirable that the first photoelectric conversion unit 20 be insensitive to the infrared range.

In the first photoelectric conversion unit 20, light entering from side on which the upper electrode 23 is disposed is absorbed by the photoelectric conversion layer 22. An exciton (a pair of an electron and a hole) generated thereby moves to an interface between the electron donor and the electron acceptor constituting the photoelectric conversion layer 22, and causes exciton separation, that is, dissociates into an electron and a hole. The charge generated here, i.e., the electron and the hole, is transferred to the upper electrode 23 or the semiconductor layer 21 by diffusion due to a difference in concentration of carriers or an internal electric field due to a difference in potential between the upper electrode 23 and the charge accumulation electrode 25, and are detected as a photocurrent. For example, the read-out electrode 26 is assumed to have a positive potential, and the upper electrode 23 is assumed to have a negative potential. In this case, the holes generated by the photoelectric conversion in the photoelectric conversion layer 22 move to the upper electrode 23. The electrons generated by the photoelectric conversion in the photoelectric conversion layer 22 are attracted to the charge accumulation electrode 25 and accumulated in the portion of the semiconductor layer 21, for example, the region portion of the semiconductor layer 21 that corresponds to the charge accumulation electrode 25, with the insulating layer 24 in between.

The charge (e.g., electrons) accumulated in the region portion of the semiconductor layer 21 that corresponds to the charge accumulation electrode 25, with the insulating layer 24 in between, is read as follows. Specifically, a potential V26 is applied to the read-out electrode 26, and a potential V25 is applied to the charge accumulation electrode 25. Here, the potential V26 is made higher than the potential V25 (V25<V26). In this way, the electrons accumulated in the region portion of the semiconductor layer 21 that corresponds to the charge accumulation electrode 25 are transferred to the read-out electrode 26.

As described above, the semiconductor layer 21 is provided below the photoelectric conversion layer 22, to accumulate the charge (e.g., electrons) in the region portion of the semiconductor layer 21 that corresponds to the charge accumulation electrode 25, with the insulating layer 24 in between. Thus, the following effects may be obtained. That is, as compared with a case where the charge (e.g., electrons) is accumulated in the photoelectric conversion layer 22 without providing the semiconductor layer 21, it is possible to prevent recombination of holes and electrons during charge accumulation, and raise transfer efficiency of the accumulated charge (e.g., electrons) to the read-out electrode 26. Moreover, it is possible to suppress generation of dark currents. Although an example where electrons are read is given in the forgoing description, holes may be read. In the case where holes are read, the potential in the forgoing description is described as a potential sensed by the holes.

### (Exemplary Cross-Sectional Configuration of OB Region 110B)

As illustrated in FIG. 3, in the OB region 110B, on the intermediate layer 40, for example, the first photoelectric conversion unit 20 extending from the effective region 110A, the sealing film 51, and the black filter 56 are provided in this order. In the OB region 110B, the contact layer 57 embedded in the sealing film 51 may be electrically coupled to the upper electrode 23 of the first photoelectric conversion unit 20. Moreover, the first photoelectric conversion unit 20 includes an edge face 20T in the OB region 110B.

### (Exemplary Cross-Sectional Configuration of Peripheral Unit 101)

In the peripheral unit 101, the structural body 200 is provided. The structural body 200 is spaced apart from and adjacent to the first photoelectric conversion unit 20. The structural body 200 is provided to be opposed to the edge face 20T of the first photoelectric conversion unit 20, for example, in a direction along the XY plane. That is, the first photoelectric conversion unit 20 and the structural body 200 are provided at the same layer level. The structural body 200 has, for example, the substantially same configuration as an entirety of the first photoelectric conversion unit 20 or a portion of the first photoelectric conversion unit 20. As used here, to have the substantially same configuration means that, for example, when the structural body 200 has a single-layer structure, the first photoelectric conversion unit 20 includes a layer of the substantially same constituent material and the substantially same thickness as a constituent material and a thickness of the structural body 200. Moreover, when the structural body 200 has a multilayer structure, the first photoelectric conversion unit 20 includes a multilayer structure in which layers of the substantially same constituent materials and the substantially same thicknesses as constituent materials and thicknesses of respective layers constituting the multilayer structure of the structural body 200 are stacked in the same order of stacking. It is to be noted that to be the substantially same means that to be regarded as the same without distinguishing a slight difference that may occur unintentionally, such as a measurement error or a manufacturing error.

Specifically, the structural body 200 includes, for example, the semiconductor layer 21, the photoelectric conversion layer 22, and the upper electrode 23 stacked in this order in the Z-axis direction. The semiconductor layer 21, the photoelectric conversion layer 22, and the upper electrode 23 constitute a part of the first photoelectric conversion unit 20. It is to be noted that, in the present embodiment, the structural body 200 is disposed on the intermediate layer 40, with the insulating layer 24 extending from the effective region 110A interposed therebetween. The structural body 200 is formed at the same time as the first photoelectric conversion unit 20, for example.

Between the first photoelectric conversion unit 20 and the structural body 200, a slit S is provided. The slit S is located at the boundary K between the pixel unit 100 and the peripheral unit 101. Here, a ratio of a width W of the slit S along the XY plane to a depth H of the slit S in the Z-axis direction may be preferably, for example, equal to or smaller than 1. One reason for this is that, for example, in forming the slit S by dry etching to separate the first photoelectric conversion unit 20 and the structural body 200, it is easy to prevent a reattached material or residue from adhering to the edge face 20T and the vicinity of the edge face 20T. It is to be noted that the width W means a width of the slit S at the lowermost part of the slit S in a depth direction (Z-axis direction). Moreover, the depth H of the slit S is, in other words, a thickness of the structural body 200.

Moreover, the slit S is preferably filled with, for example, an insulating material such as the sealing film 51. When AlO is used as the constituent material of the sealing film 51 filling the slit S, the width W of the slit S is preferably, for example, equal to or greater than 100 nm. One reason for this is that, when the width W of the slit S is equal to or greater than 100 nm, it is possible to fill the slit S with the sealing film 51 including AlO by a sputtering method. In a case where the width W of the slit S is smaller than 100 nm, there is possibility that a gap is formed inside the sealing film 51 when forming the sealing film 51 including AlO by the sputtering method. In a case where the slit S is not tightly filled with the insulating material, that is, in a case where the sealing film 51 includes a gap, there is possibility that a gas present in the gap escapes to outside the sealing film 51, thereby affecting film quality and optical characteristics of the photoelectric conversion layer 22.

### (Read-Out Circuit of Second Photoelectric Conversion Unit 10)

FIG. 4 is a circuit diagram illustrating an exemplary read-out circuit of the second photoelectric conversion unit 10 constituting the pixel P illustrated in FIG. 2A.

The read-out circuit of the second photoelectric conversion unit 10 includes, for example, the TGs 14A and 14B, an OFG 146, the FDs 15A and 15B, the RSTs 143A and 143B, the AMPs 144A and 144B, and the SELs 145A and 145B.

The TG 14A is coupled to between the photoelectric conversion region 12 and the FD 15A, and the TG 14B is coupled to between the photoelectric conversion region 12 and the FD 15B. When a drive signal is applied to gate electrodes of the TGs 14A and 14B, bringing the TGs 14A and 14B into an active state, transfer gates of the TGs 14A and 14B are brought into an electrically conductive state. As a result, the signal charge converted in the photoelectric conversion region 12 is transferred to the FDs 15A and 15B through the TGs 14A and 14B.

The OFG 146 is coupled to between the photoelectric conversion region 12 and a power supply. When a drive signal is applied to a gate electrode of the OFG 146, bringing the OFG 146 into the active state, the OFG 146 is brought into the electrically conductive state. As a result, the signal charge converted in the photoelectric conversion region 12 is discharged to the power supply through the OFG 146.

The FD 15A is coupled between the TG 14A and the AMP 144A, and the FD15B is coupled to between the TG 14B and the AMP 144B. The FDs 15A and 15B makes a charge-voltage conversion of the signal charge transferred by the TGs 14A and 14B into a voltage signal, and output the voltage signal to the AMPs 144A and 144B.

The RST 143A is coupled to between the FD 15A and the power supply, and the RST 143B is coupled to between the FD 15B and the power supply. When a drive signal is applied to gate electrodes of the RSTs 143A and 143B, bringing the RSTs 143A and 143B into the active state, reset gates of the RSTs 143A and 143B are brought into the electrically conductive state. As a result, potentials of the FDs 15A and 15B are reset to a level of the power supply.

The AMPs 144A and 144B have gate electrodes coupled to the FDs 15A and 15B and drain electrodes coupled to the power supply, respectively. The AMPs 144A and 144B serve as an input section of a read-out circuit of the voltage signal held by the FDs 15A and 15B, i.e., a so-called source follower circuit. That is, source electrodes of the AMPs 144A and 144B are coupled to the vertical signal line Lsig through the SELs 145A and 145B, respectively, to constitute a source follower circuit together with a constant current source coupled to one end of the vertical signal line Lsig.

The SELs 145A and 145B are coupled to between source electrodes of the AMPS 144A and 144B and the vertical signal line Lsig, respectively. When a drive signal is applied to gate electrodes of the SELs 145A and 145B, bringing the SELs 145A and 145B into the active state, the SELs 145A and 145B are brought into the electrically conductive state, bringing the pixel P into a selected state. Thus, a read signal (a pixel signal) outputted from the AMPs 144A and 144B is outputted to the vertical signal line Lsig through the SELs 145A and 145B, respectively.

In the solid-state imaging apparatus 1, the object is irradiated with light pulses in the infrared range. Light pulses reflected from the object is received in the photoelectric conversion region 12 of the second photoelectric conversion unit 10. In the photoelectric conversion region 12, entry of the light pulses in the infrared range causes generation of multiple charges. The multiple charges generated in the photoelectric conversion region 12 are alternately distributed to the FD 15A and the FD 15B by alternately supplying the drive signal to the pair of the TGs 14A and 14B for equal periods of time. By changing a shutter phase of the drive signal to be applied to the TGs 14A and 14B with respect to the irradiating light pulses, an accumulated amount of the charge in the FD 15A and an accumulated amount of the charge in the FD 15B become phase-modulated values. By demodulating these values, round-trip time of the light pulses is estimated. Thus, a distance from the solid-state imaging apparatus 1 to the object is determined.

### (Read-Out Circuit of First Photoelectric Conversion Unit 20)

FIG. 5 is a circuit diagram illustrating an exemplary read-out circuit of the first photoelectric conversion unit 20 constituting the pixel P1 illustrated in FIG. 2A.

The read-out circuit of the first photoelectric conversion unit 20 includes, for example, the FD 131, an RST 132, the AMP 133, and an SEL 134.

The FD 131 is coupled to between the read-out electrode 26 and the AMP 133. The FD 131 converts the signal charge transferred by the read-out electrode 26 into a voltage signal and outputs the voltage signal to the AMP 133.

The RST 132 is coupled to between the FD 131 and the power supply. When a drive signal is applied to a gate electrode of the RST 132, bringing the RST 132 into the active state, a reset gate of the RST 132 is brought into the electrically conductive state. As a result, a potential of the FD 131 is reset to the level of the power supply.

The AMP 133 has a gate electrode coupled to the FD 131 and a drain electrode coupled to the power supply. A source electrode of the AMP 133 is coupled to the vertical signal line Lsig through the SEL 134.

The SEL 134 is coupled to between the source electrode of the AMP 133 and the vertical signal line Lsig. When a drive signal is applied to a gate electrode of the SEL 134, bringing the SEL 134 into the active state, the SEL 134 is brought into the electrically conductive state, bringing the pixel P1 into the selected state. Thus, a read signal (pixel signal) outputted from the AMP 133 is outputted to the vertical signal line Lsig through the SEL 134.

### [Manufacturing Method of Solid-State Imaging Apparatus 1]

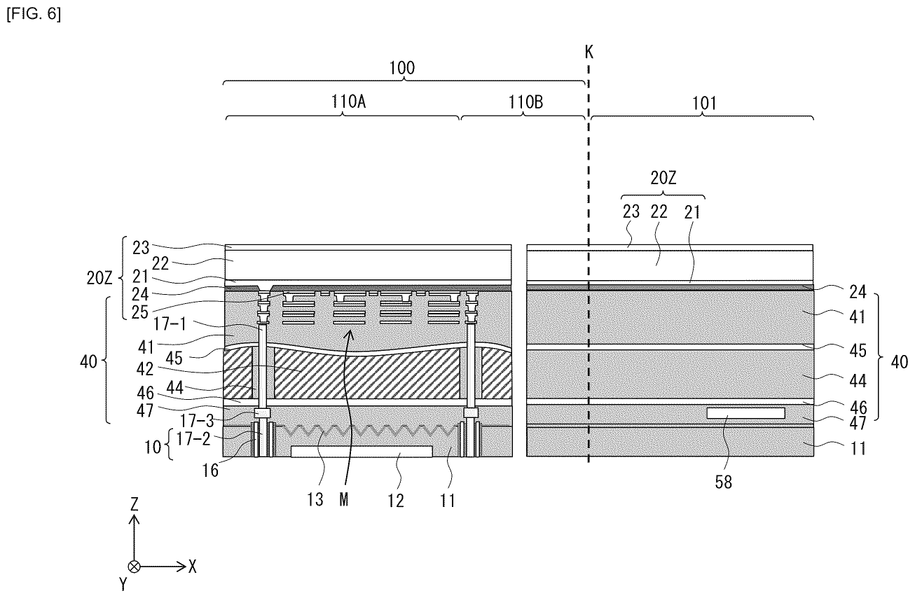

FIGS. 6 to 9 are each a vertical cross-sectional view or a plan view illustrating a process in a method of manufacturing the solid-state imaging apparatus 1 of the present embodiment. Here, description is given mainly of a method of manufacturing the first photoelectric conversion unit 20 and the structural body 200.

First, the insulating layer 47, the SiN layer 46, the inter-pixel region light shielding wall 44, the optical filter 42, the SiN layer 45, and the insulating layer 41 are formed in this order on the semiconductor substrate 11 including the second photoelectric conversion unit 10, to form the intermediate layer 40. In the insulating layer 47, the coupling electrode section 17-3 is embedded. In the insulating layer 41, the wiring layer M is embedded. Next, the through-electrode 17 is formed in an inter-pixel region. The through-electrode 17 extends in the Z-axis direction.

Thereafter, as illustrated in FIG. 6, for example, a multi-layer film 20Z is entirely formed on the intermediate layer 40. Specifically, the charge accumulation electrode 25, the insulating layer 24, the semiconductor layer 21, the photoelectric conversion layer 22, and the upper electrode 23 are formed in this order. The charge accumulation electrode 25 is coupled to the wiring layer M. The insulating layer 24, the semiconductor layer 21, the photoelectric conversion layer 22, and the upper electrode 23 are formed to extend from the pixel unit 100 to the peripheral unit 101.

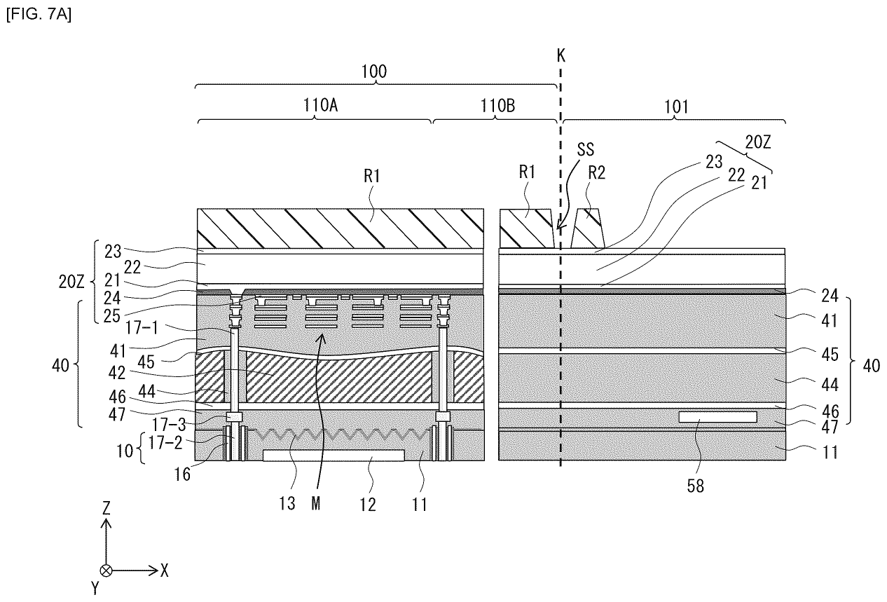

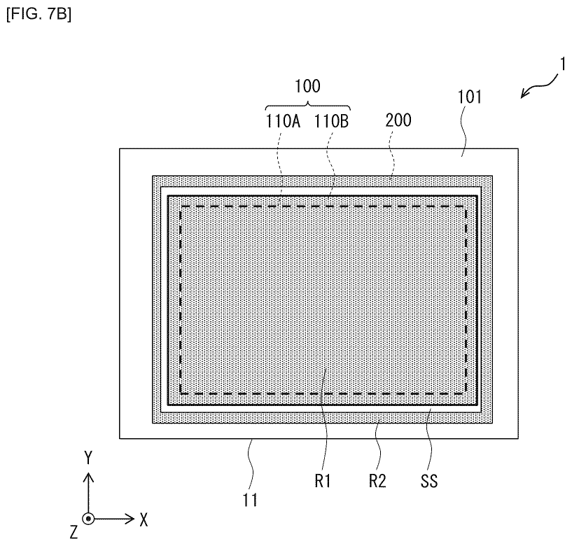

Next, as illustrated in FIGS. 7A and 7B, for example, resist films R1 and R2 are selectively formed on the multi-layer film 20Z. It is to be noted that FIG. 7A is a vertical cross-sectional view illustrating an intermediate product in a process subsequent to FIG. 6. FIG. 7B is a plan view of the intermediate product in FIG. 7A as viewed from above. The resist film R1 is formed to cover a region where the first photoelectric conversion unit 20 is to be formed. The resist film R2 is formed to surround the resist film R1 in the XY plane, to cover a region where the structural body 200 is to be formed. Accordingly, a slit SS is formed between the resist film R1 and the resist film R2 directly above a position where the slit S is to be formed.

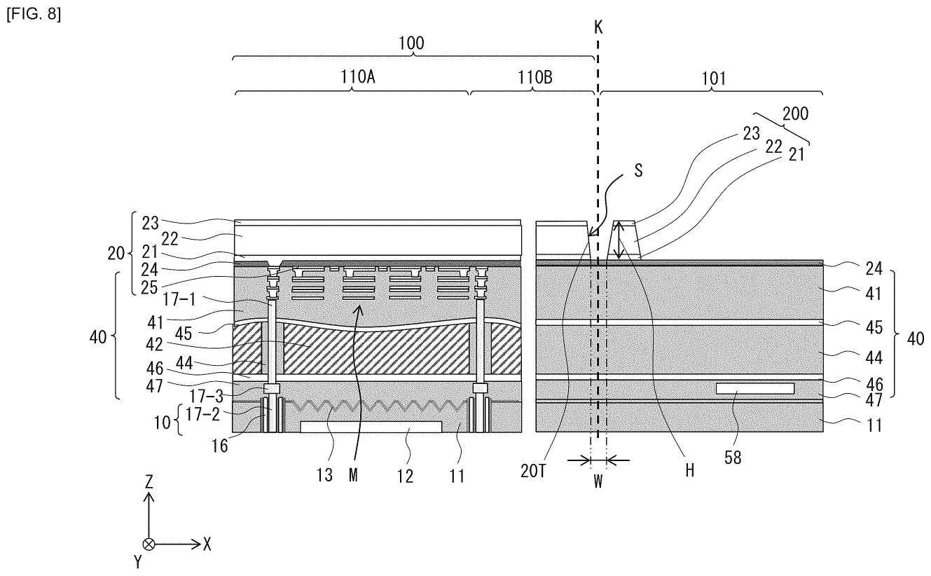

Subsequently, the multi-layer film 20Z is dry-etched using the resist films R1 and R2 as a mask. Here, for example, a portion of the multi-layer film 20Z that is not covered by the resist films R1 and R2 is removed until the insulating layer 24 is exposed. Thus, as illustrated in FIG. 8, the first photoelectric conversion unit 20 and the structural body 200 are formed. The first photoelectric conversion unit 20 and the structural body 200 are separated from each other by the slit S.

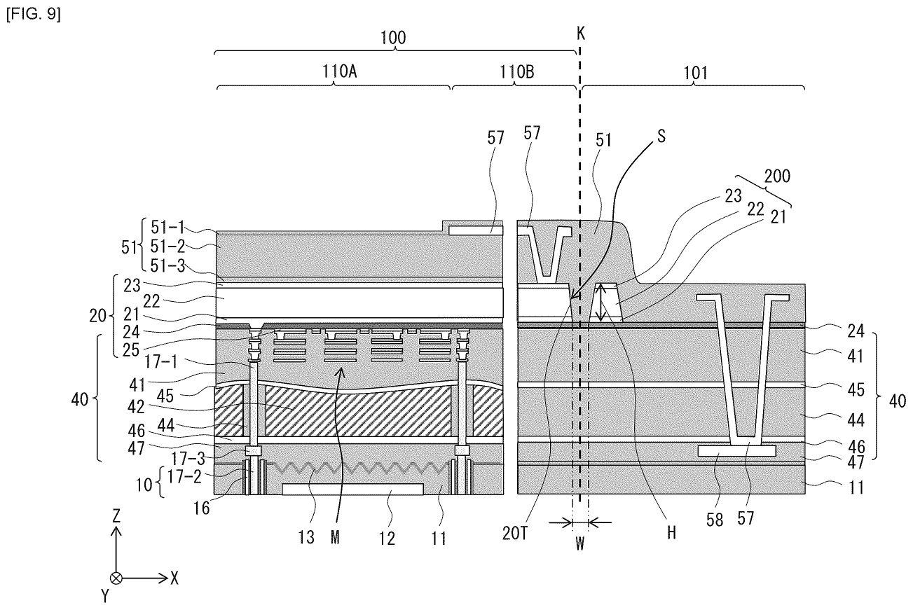

Next, as illustrated in FIG. 9, for example, the sealing film 51 is formed to cover the first photoelectric conversion unit 20 and the structural body 200, and to fill the slit S therebetween. The sealing film 51 may be formed by, for example, a sputtering method. However, for example, an ALD method or the like may be used depending on the width W and depth H of the slit S, and the constituent material of the sealing film 51. In the process of forming the sealing film 51, the contact layer 57 is formed.

Thereafter, the low refractive index layer 52, the color filters 53, the lens layer 54, the antireflection film 55, the black filter 56, and the like are formed, thereby completing the solid-state imaging apparatus 1.

### [Workings and Effects of Solid-State Imaging Apparatus 1]

The solid-state imaging apparatus 1 of the present embodiment includes the first photoelectric conversion unit 20 and the structural body 200. The first photoelectric conversion unit 20 is provided in the pixel unit 100. The structural body 200 is provided in the peripheral unit 101 adjacent to the pixel unit 100, and is spaced apart from and adjacent to the first photoelectric conversion unit 20 along the XY plane. This makes it possible to cover an exposed portion of the insulating layer 24 or the insulating layer 41 with the structural body 200 as a dummy pattern. The insulating layer 24 and the insulating layer 41 are base insulating films formed in the peripheral unit 101. Moreover, the first photoelectric conversion unit 20 and the structural body 200 are separated from each other. Thus, for example, in patterning the first photoelectric conversion unit 20 by dry etching, generation of residue on the edge face 20T of the first photoelectric conversion unit 20 and in the vicinity thereof is suppressed. It is to be noted that, because the structural body 200 is provided to be spaced apart from the first photoelectric conversion unit 20, light reception by the structural body 200 disposed in the peripheral unit 101 as a region other than the pixel unit 100 does not affect the operation of the first photoelectric conversion unit 20.

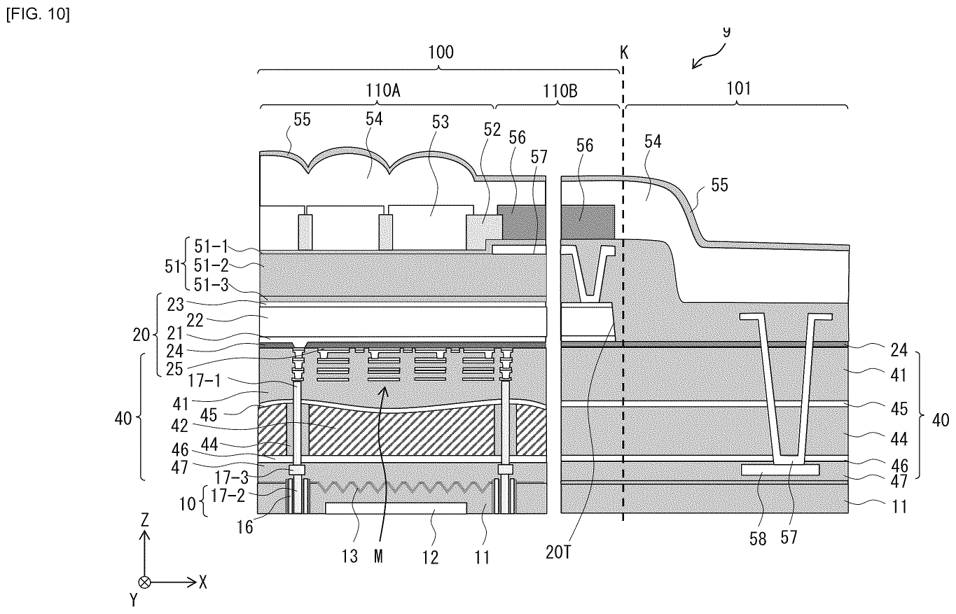

In the following, detailed description is given of workings and effects of the solid-state imaging apparatus 1, with reference to a solid-state imaging apparatus 9 as a reference example illustrated in FIG. 10. FIG. 10 is a vertical cross-sectional view illustrating, in an enlarged manner, a portion of the solid-state imaging apparatus 9 as the reference example, and corresponds to FIG. 3 for the solid-state imaging apparatus 1. A configuration of the solid-state imaging apparatus 9 is substantially the same as the configuration of the solid-state imaging apparatus 1 except that no structural bodies 200 are provided in the peripheral unit 101.

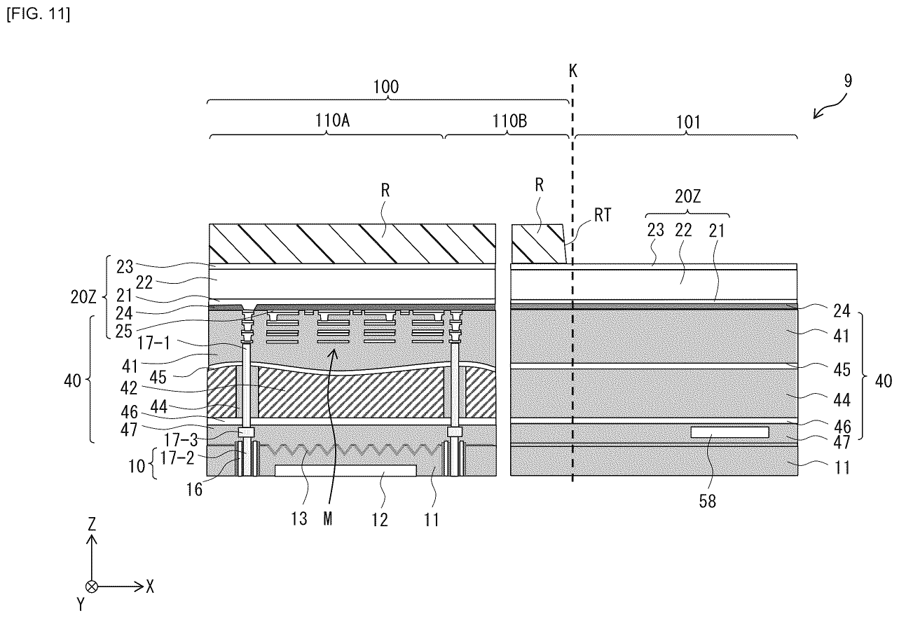

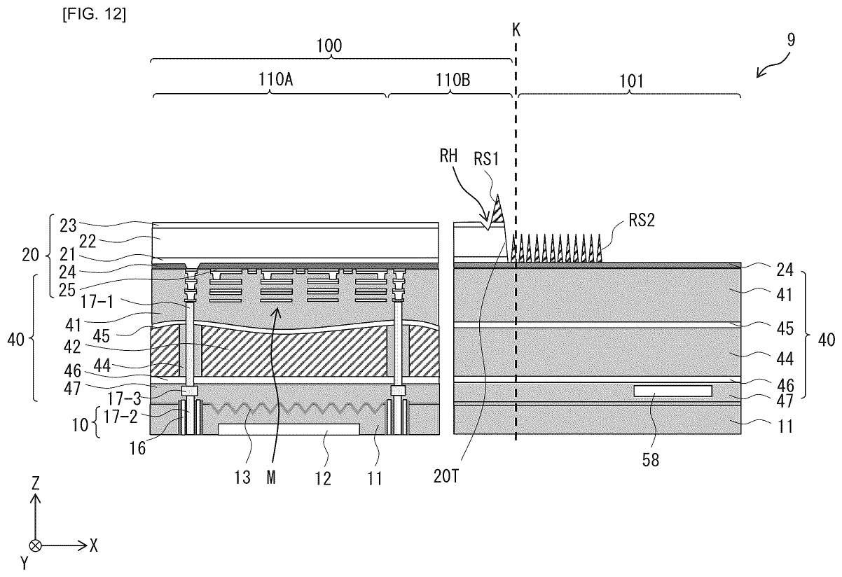

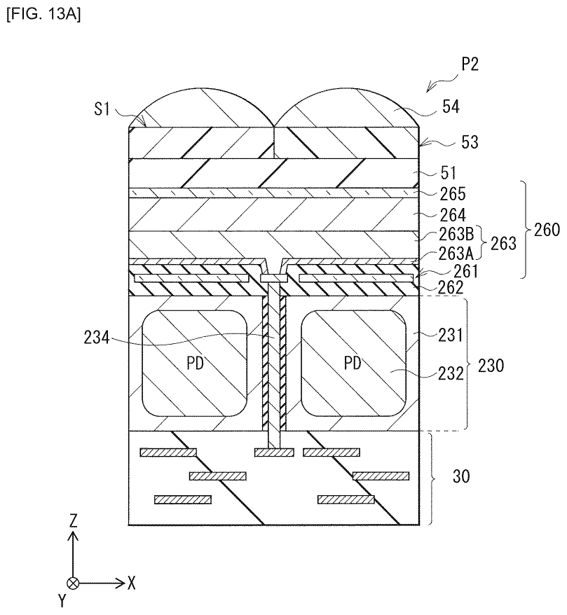

In manufacturing the solid-state imaging apparatus 9 in FIG. 10, for example, as illustrated in FIG. 11, after the multi-layer film 20Z is formed, a resist film R is formed only in a region corresponding to the region where the first photoelectric conversion unit 20 is to be formed. Thereafter, as illustrated in FIG. 12, the first photoelectric conversion unit 20 is obtained by selectively removing a portion of the multi-layer film 20Z that is not covered with the resist film R, for example, by dry etching. However, in this case, a portion of the multi-layer film 20Z to be removed becomes residue RS1 and the residue RS1 often reattaches to the vicinity of the edge face 20T of the first photoelectric conversion unit 20. The residue RS1 is formed, for example, in a wall-like shape in an upper portion near the edge face 20T of the first photoelectric conversion unit 20. Furthermore, behind the wall-shaped residue RS1, that is, in the first photoelectric conversion unit 20 on opposite side to the edge face 20T as seen from the residue RS1, a hole RH is easily formed. The hole RH is generated because a portion of the first photoelectric conversion unit 20 is locally etched by generation of the residue RS1. Accordingly, if the hole RH is formed to some depth, there is possibility that a short circuit occurs between the upper electrode 23 and the semiconductor layer 21. Moreover, because the residue RS1 easily adheres to the edge face 20T, a short circuit may also easily occur between the upper electrode 23 and the semiconductor layer 21. Such a phenomenon is caused by removal of a portion of the multi-layer film 20Z that covers the peripheral unit 101. Furthermore, when a metallic oxide containing, for example, In (indium), Zn (zinc), and gallium (Ga) is used together with an organic film in the multi-layer film 20Z, residue RS1 is easily generated. One reason for this is that they are difficult to be removed by dry etching. For example, in some cases, it is possible to suppress the generation of the residue RS1 by adjusting an angle of inclination of an edge face RT (see FIG. 11) of the resist film R. For example, when the angle of inclination of the edge face RT is made gentle, that is, when an angle formed with respect to an upper surface of the insulating layer 24 along the XY plane is made small, the residue RS1 tends to be reduced. However, in this case, as illustrated in FIG. 12, needle-shaped residue RS2 tends to remain on the upper surface of the insulating layer 24. If the needle-shaped residue RS2 remains, there is a concern about influences such as an increase in variations in film quality and thickness of, for example, the sealing film 51 to be formed in subsequent processes.

In this regard, in the solid-state imaging apparatus 1 of the present embodiment, the structural body 200 is provided in the peripheral unit 101 adjacent to the pixel unit 100. That is, it is possible to pattern the multi-layer film 20Z to leave the structural body 200 as the dummy pattern. This makes it possible to reduce a total amount of the removed portion of the multi-layer film 20Z, as compared with the solid-state imaging apparatus 9 as the reference example illustrated in FIG. 10. Hence, it is possible to reduce an amount of residue generated. Moreover, the structural body 200 is arranged to be adjacent to the first photoelectric conversion unit 20, with the slit S located at the boundary K in between. This makes it possible to suppress the residue from adhering to the edge face 20T of the first photoelectric conversion unit 20 and the vicinity of the edge face 20T. In particular, the ratio of the width W of the slit S to the depth of the slit S is set to be equal to or smaller than 1. This makes it possible to more effectively suppress the residue from adhering to the edge face 20T of the first photoelectric conversion unit 20 and the vicinity of the edge face 20T.

Moreover, the solid-state imaging apparatus 1 of the present embodiment includes the first photoelectric conversion unit 20, the optical filter 42, and the photoelectric conversion unit 10 that are stacked in this order from the light-entering side. The first photoelectric conversion unit 20 detects light having a wavelength in the visible light range and performs the photoelectric conversion. The optical filter 42 has the transmission band in the infrared light range. The second photoelectric conversion unit 10 detects light having a wavelength in the infrared light range and performs the photoelectric conversion. Accordingly, it is possible to acquire a visible light image and an infrared light image at the same time and at the same position in the XY in-plane direction. The visible light image is constituted by a red light signal, a green light signal, and a blue light signal obtained from a red pixel PR, a green pixel PG, and a blue pixel PB, respectively. The infrared light image uses infrared light signals acquired from all the multiple pixels P. Hence, it is possible to achieve high integration in the XY in-plane direction.

Further, the second photoelectric conversion unit 10 includes the pair of the TGs 14A and 14B, and the pair of the FDs 15A and 15B. This makes it possible to acquire the infrared light image as the distance image including information regarding a distance to the object. Hence, according to the solid-state imaging apparatus 1 of the present embodiment, it is possible to provide a balance between acquisition of the high-resolution visible light image and acquisition of the infrared light image including depth information.

Further, in the pixel P1 of the present embodiment, the inter-pixel region light shielding wall 44 is provided. The inter-pixel region light shielding wall 44 surrounds the optical filter 42. This makes it possible to suppress leakage light from another adjacent pixel P1 or unwanted light from the surroundings from entering the second photoelectric conversion unit 10 directly or through the optical filter 42. Hence, it is possible to reduce noises to be received by the second photoelectric conversion unit 10, and to expect improvements in an S/N ratio, resolution, ranging accuracy, and the like of the solid-state imaging apparatus 1.

Moreover, in the pixel P1 of the present embodiment, the first photoelectric conversion unit 20 includes the insulating layer 24 and the charge accumulation electrode 25 in addition to the structure in which the read-out electrode 26, the semiconductor layer 21, the photoelectric conversion layer 22, and the upper electrode 23 are stacked in this order. The insulating layer 24 is provided below the semiconductor layer 21. The charge accumulation electrode 25 is provided opposed to the semiconductor layer 21, with the insulating layer 24 interposed therebetween. This makes it possible to accumulate the charge generated by the photoelectric conversion in the photoelectric conversion layer 22, in the portion of the semiconductor layer 21, for example, the region portion of the semiconductor layer 21 that corresponds to the charge accumulation electrode 25, with the insulating layer 24 in between. Accordingly, it is possible to remove charges from the semiconductor layer 21 at the start of exposure, for example. That is, it is possible to achieve complete depletion of the semiconductor layer 21. As a result, it is possible to reduce kTC noises, leading to suppression of deterioration of image quality due to random noises. Furthermore, as compared with the case where the charge (e.g., electrons) is accumulated in the photoelectric conversion layer 22 without providing the semiconductor layer 21, recombination of holes and electrons during charge accumulation is prevented. Hence, it is possible to raise transfer efficiency of the accumulated charge (e.g., electrons) to the read-out electrode 26, and to suppress the generation of dark currents.

### 2. FIRST MODIFICATION EXAMPLE

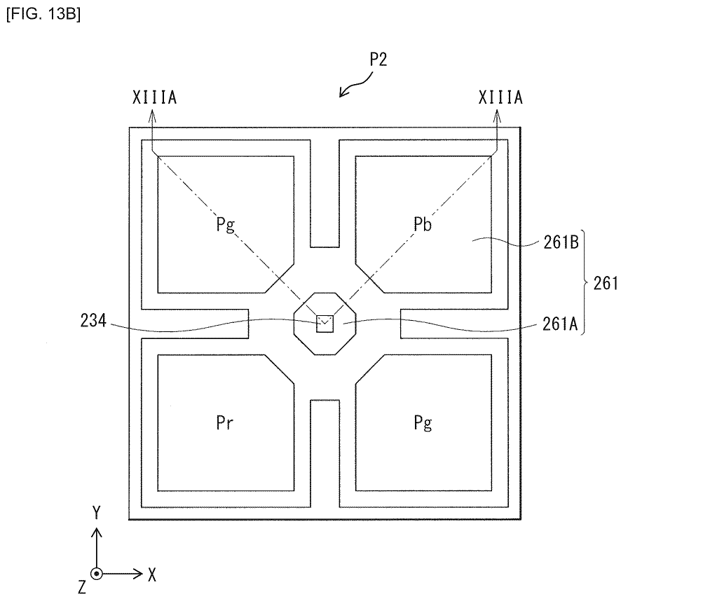

FIG. 13A schematically illustrates an exemplary vertical cross-sectional configuration of a pixel P2 according to a first modification example (modification example 1) applicable to the pixel unit 100 of the solid-state imaging apparatus 1 according to the forgoing embodiment. FIG. 13B schematically illustrates an exemplary plan configuration of the pixel P2 illustrated in FIG. 13A. It is to be noted that FIG. 13A illustrates a cross-section along a line XIII-XIII illustrated in FIG. 13B. The pixel P2 is, for example, an imaging element of a stacked type in which a second photoelectric conversion unit 232 and a first photoelectric conversion unit 260 are stacked. In the pixel unit 100 of the solid-state imaging apparatus 1 including the pixel P2, as illustrated in FIG. 13B, a subpixel unit serves as a unit of repeat. The subpixel unit includes, for example, four subpixels arranged in two rows by two columns. The subpixel units are repeatedly arranged in an array in a row direction and in a column direction.

In the pixel P2, the color filters 53 are provided for each unit pixel P2 above the first photoelectric conversion unit 260 (light-entering side S1). The color filters 53 selectively transmit red light (R), green light (G), and blue light (B). Specifically, in the sub-pixel unit including the four sub-pixels arranged in two rows by two columns, two color filters that selectively transmit green light (G) are arranged on a diagonal line. One color filter that selectively transmits red light (R) and one color filter that selectively transmits blue light (B) are arranged on another diagonal line orthogonal to the diagonal line. In the unit pixel (Pr, Pg, Pb) provided with the respective color filters, for example, light of corresponding colors is detected in the first photoelectric conversion unit 260. That is, in the pixel unit 100, the pixels (Pr, Pg, Pb) that detect red light (R), green light (G), and blue light (B) are arranged in the Bayer array.

The first photoelectric conversion unit 260 includes, for example, a lower electrode 261, an interlayer insulating layer 262, a semiconductor layer 263, a photoelectric conversion layer 264, and an upper electrode 265. The first photoelectric conversion unit 260 has a similar configuration to the first photoelectric conversion unit 20 in the forgoing embodiment. The second photoelectric conversion unit 232 detects light in a wavelength range different from that of the first photoelectric conversion unit 260.

In the pixel P2, within the light having passed through the color filters 53, the light (red light (R), green light (G), and blue light (B)) in the visible light range is absorbed by the first photoelectric conversion unit 260 of the subpixels (Pr, Pg, Pb) provided with the respective color filters. The other light, for example, the light (infrared light (IR)) in the infrared light range (for example, 700 nm to 1000 nm, both inclusive) passes through the first photoelectric conversion unit 260. The infrared light (IR) having passed through the first photoelectric conversion unit 260 is detected by the second photoelectric conversion unit 232 of each sub-pixel Pr, Pg, and Pb. In each sub-pixel Pr, Pg, and Pb, the signal charge corresponding to the infrared light (IR) is generated. That is, the solid-state imaging apparatus 1 including the pixel P2 is configured to simultaneously generate both a visible light image and an infrared light image.

### 3. SECOND MODIFICATION EXAMPLE

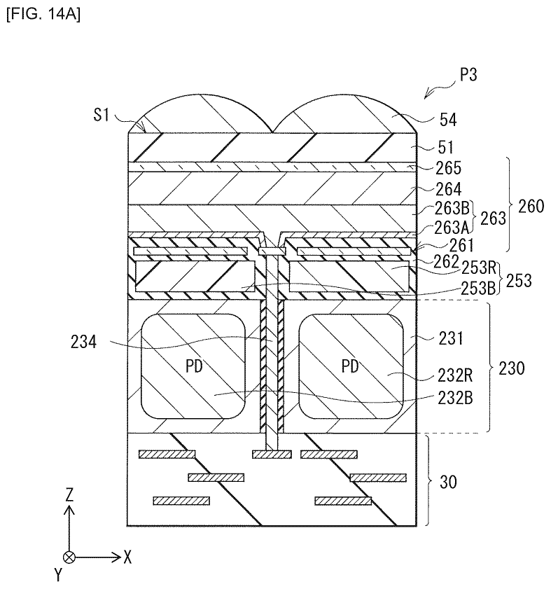

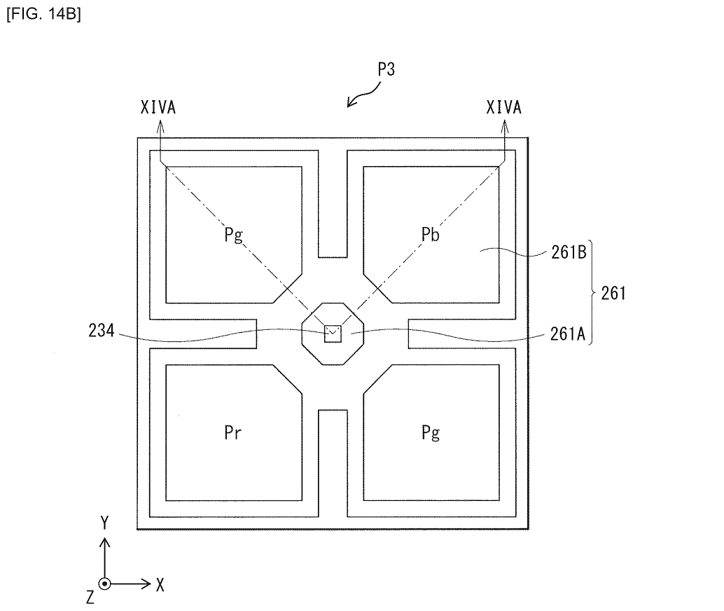

FIG. 14A schematically illustrates an exemplary vertical cross-sectional configuration of a pixel P3 according to a second modification example (modification example 2) applicable to the pixel unit 100 of the solid-state imaging apparatus 1 according to the forgoing embodiment. FIG. 14B schematically illustrates an exemplary plan configuration of the pixel P3 illustrated in FIG. 14A. It is to be noted that FIG. 14A illustrates a cross-section along a line XIV-XIV illustrated in FIG. 14B. In the forgoing modification example 1, the example is given in which the color filters 53 are provided above the first photoelectric conversion unit 260 (light-entering side S1). The color filters 53 selectively transmit red light (R), green light (G), and blue light (B). However, for example, as illustrated in FIG. 14A, color filters 253 may be provided between the second photoelectric conversion unit 232 and the first photoelectric conversion unit 260.

In the pixel P3, for example, the color filters 253 have a configuration in which a color filter (color filter 253R) that selectively transmits at least red light (R) and a color filter (color filter 253B) that selectively transmits at least blue light (B) are arranged diagonally to each other in the sub-pixel unit. The first photoelectric conversion unit 260 (the photoelectric conversion layer 264) is configured to selectively absorb a wavelength corresponding to, for example, green light. This makes it possible for the second photoelectric conversion unit (second photoelectric conversion units 232R and 232G) disposed below the first photoelectric conversion unit 260 and the color filters 253R and 253B to acquire signals corresponding to RGB. In the pixel P3, it is possible to increase the area of each of the first photoelectric conversion units 260 in RGB as compared with those of the imaging elements in the general Bayer array. Hence, it is possible to enhance an S/N ratio.

### 4. THIRD MODIFICATION EXAMPLE

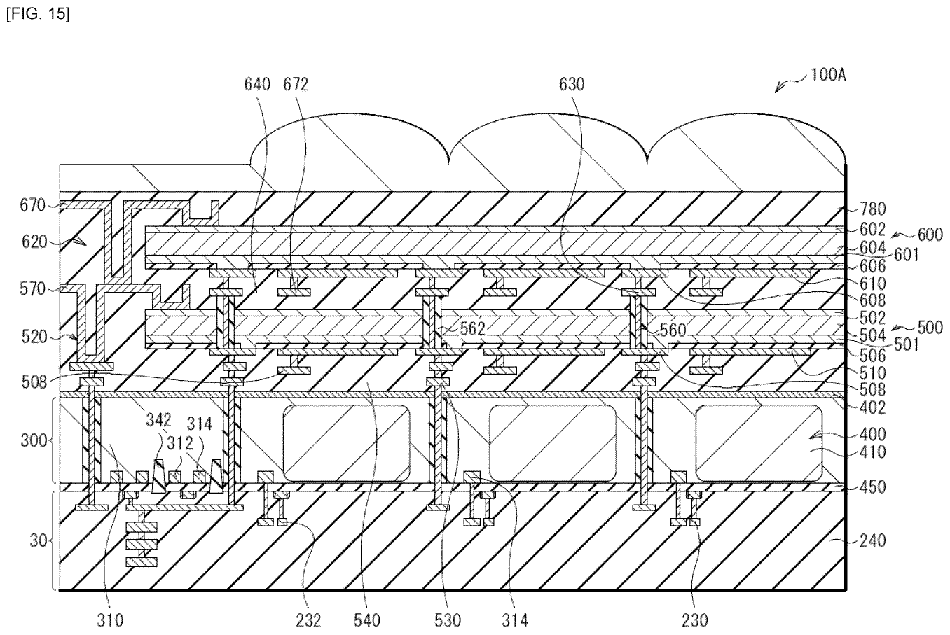

FIG. 15 is a vertical cross-sectional view illustrating an exemplary overall configuration of a pixel unit 100A according to a third modification example applicable to the solid-state imaging apparatus 1 illustrated in FIG. 1A. In FIG. 15, the pixel unit 100A is illustrated, with a light-entering face upside. The light-entering face is a face through which light enters each pixel. In the following description, a stacked structure of the pixel unit 100A is described in the order from a semiconductor substrate 300 toward a PD 500 (second photoelectric conversion unit) and a PD 600 (first photoelectric conversion unit). The semiconductor substrate 300 is positioned on lower side of the pixel unit 100A. The PD 500 is provided above the semiconductor substrate 300. The PD 600 is provided above the PD 500.

Specifically, as illustrated in FIG. 15, in the pixel unit 100A, a semiconductor region 410 is provided in the semiconductor region 310 of the semiconductor substrate 300 including, for example, silicon. The semiconductor region 310 has a first conductivity type (for example, P-type). The semiconductor region 410 has a second conductivity type (for example, N-type). By such a PN junction by the semiconductor region 410, a PD 400 that converts light into electric charge is formed in the semiconductor substrate 300. It is to be noted that, in this modification example, the PD 400 is, for example, a photoelectric conversion element that absorbs red light (for example, light having a wavelength of 600 nm to 700 nm) and generates the electric charge.

Moreover, in the present embodiment, a semiconductor layer 501 and a photoelectric conversion film 504 are provided on a wiring layer 520. The semiconductor layer 501 and the photoelectric conversion film 504 are provided to be interposed between a common electrode (an upper electrode) 502 and a read-out electrode 508. The common electrode 502 is shared by the adjacent pixels. The read-out electrode 508 reads out electric charge generated in the photoelectric conversion film 504. The common electrode 502, the photoelectric conversion film 504, the semiconductor layer 501, and the read-out electrode 508 constitute a portion of a stacked structure of the PD 500 (the second photoelectric conversion unit) that converts light into electric charge. In this modification example, the relevant PD 500 is, for example, a photoelectric conversion element that absorbs green light (for example, light having a wavelength of 500 nm to 600 nm) and generates the electric charge (photoelectric conversion).

Furthermore, in the present modification example, the PD 600 (the second photoelectric conversion unit) that converts light into electric charge is provided on a wiring layer 620. The relevant PD 600 is, for example, a photoelectric conversion element that absorbs blue light (for example, light having a wavelength of 400 nm to 500 nm) and generates the electric charge (photoelectric conversion). Specifically, as the PD 600, a common electrode (an upper electrode) 602, a photoelectric conversion film 604, a semiconductor layer 601, an insulating film 606, a read-out electrode (a lower electrode) 608, and an accumulation electrode 610 are stacked in this order.

It is to be noted that, in the present modification example, in the PD 500 and the PD 600, the order of stacking the layers does not have to be the order described above. The layers may be stacked in the order in which the layers are stacked in symmetrical relation in a direction of stacking. Moreover, in the present embodiment, when the pixel unit 100A is viewed from above the light-entering face, for example, the read-out electrodes 508 and 608, and the accumulation electrodes 510 and 610 of the PD 500 and the PD 600 do not have to be completely superposed on one another. In other words, in the present embodiment, when the pixel unit 100A is viewed from above the light-entering face, a layout of the layers of the PDs 500 and 600 is not particularly limited.

As described above, the pixel unit 100A of the present modification example has the stacked structure in which the PD 400, the PD 500, and the PD 600 are stacked. The PD 400, the PD 500, and the PD 600 detect light in the respective three colors. That is, it can be said that the pixel unit 100A described above is, for example, the vertical spectroscopic solid-state imaging element in which blue light is photoelectrically converted by the photoelectric conversion film 604 (the PD 600) formed above the semiconductor substrate 300, green light is photoelectrically converted by the photoelectric conversion film 504 (the PD 500) provided below the PD 600, and red light is photoelectrically converted by the PD 400 provided in the semiconductor substrate 300. It is to be noted that, in the present modification example, the pixel unit 100A described above is not limited to the vertical spectroscopic stacked structure as described above. For example, green light may be photoelectrically converted by the photoelectric conversion film 604 (the PD 600) formed above the semiconductor-substrate 300, and blue light may be photoelectrically converted by the photoelectric conversion film 504 (the PD 500) provided below the PD 600.

### 5. SECOND EMBODIMENT

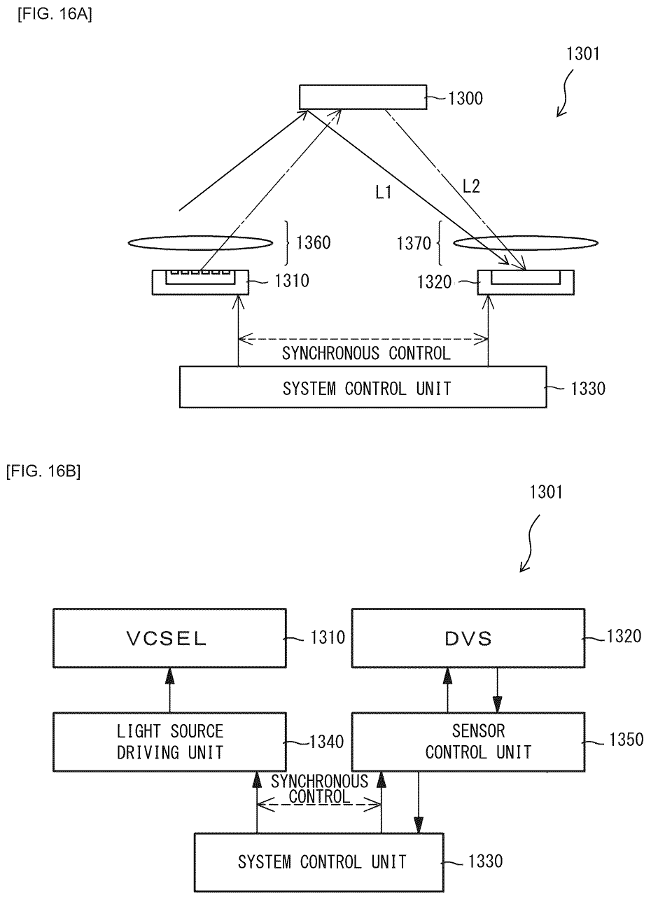

FIG. 16A is a schematic diagram illustrating an exemplary overall configuration of a light detection system 1301 according to a second embodiment of the present disclosure. FIG. 16B is a schematic diagram illustrating an exemplary circuit configuration of the light detection system 1301. The light detection system 1301 includes a light-emitting apparatus 1310 as a light source that emits light L2, and a light detection apparatus 1320 as a light-receiving unit that includes a photoelectric conversion element. As the light detection apparatus 1320, the above-described solid-state imaging apparatus 1 may be used. The light detection system 1301 may further include a system control unit 1330, a light source driving unit 1340, a sensor control unit 1350, a light-source-side optical system 1360, and a camera-side optical system 1370.

The light detection apparatus 1320 is configured to detect light L1 and light L2. The light L1 is external environment light reflected from an object (an object to be measured) 1300 (FIG. 16A). The light L2 is light emitted from the light-emitting apparatus 1310 and then reflected from the object 1300. The light L1 is, for example, visible light, and the light L2 is, for example, infrared light. The light L1 is detectable by an organic photoelectric conversion unit in the light detection apparatus 1320, and the light L2 is detectable by a photoelectric conversion unit in the light detection apparatus 1320. Image information regarding the object 1300 may be acquired from the light L1, and distance information regarding a distance from the object 1300 to the light detection system 1301 may be acquired from the light L2. The light detection system 1301 may be mounted on, for example, electronic equipment such as a smartphone or a mobile body such as a car. The light-emitting apparatus 1310 may be configured by, for example, a semiconductor laser, a surface-emitting semiconductor laser, or a vertical-cavity surface-emitting laser (VCSEL). As a method of detecting the light L2 emitted from the light-emitting apparatus 1310 by the light detection apparatus 1320, for example, an iTOF method may be employed; however, the method is not limited thereto. In the iTOF method, it is possible for a photoelectric conversion unit to measure the distance to the object 1300 on the basis of, for example, optical time-of-flight (Time-of-Flight;TOF). As a method of detecting the light L2 emitted from the light-emitting apparatus 1310 by light detection apparatus 1320, for example, a structured light method or a stereo-vision method may be also employed. For example, in the structured light method, it is possible to measure the distance from the light detection system 1301 to the object 1300 by projecting light of a predetermined pattern onto the object 1300 and analyzing a degree of distortion of the pattern. Further, in the stereo-vision method, it is possible to measure the distance from the light detection system 1301 to the object by capturing two or more images of the object 1300 viewed from two or more different viewpoints using, for example, two or more cameras. It is to be noted that it is possible to make a synchronous control of the light-emitting apparatus 1310 and the light detection apparatus 1320 by the system control unit 1330.

### 6. EXEMPLARY APPLICATION TO ELECTRONIC EQUIPMENT

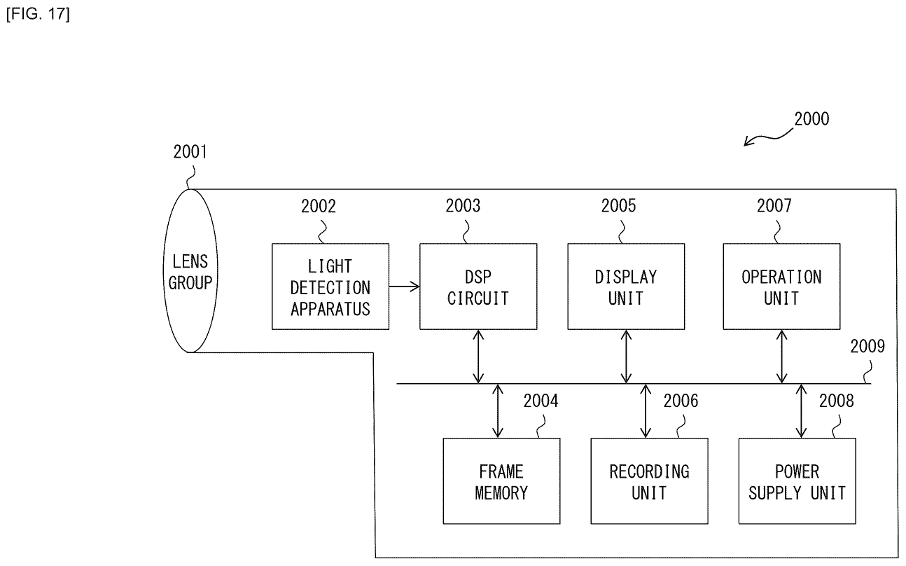

FIG. 17 is a block diagram illustrating a configuration example of electronic equipment 2000 to which the present technology is applied. The electronic equipment 2000 has a function as a camera, for example.

The electronic equipment 2000 includes an optical unit 2001 including a lens group or the like, a light detection apparatus 2002 to which the above-described solid-state imaging apparatus 1 or the like (hereinafter, referred to as the solid-state imaging apparatus 1 and the like) is applied, and a digital signal processor (DSP) circuit 2003 that is a camera signal processing circuit. The electronic equipment 2000 further includes a frame memory 2004, a display unit 2005, a recording unit 2006, an operation unit 2007, and a power supply unit 2008. The DSP circuit 2003, the frame memory 2004, the display unit 2005, the recording unit 2006, the operation unit 2007, and the power supply unit 2008 are coupled to each other through a bus line 2009.

The optical unit 2001 takes in entering light (image light) from the object and forms an image on an imaging plane of the light detection apparatus 2002. The light detection apparatus 2002 converts an amount of entering light focused on the imaging plane by the optical unit 2001 into an electric signal on the pixel-by-pixel basis, and outputs the electric signal as a pixel signal.

The display unit 2005 includes, for example, a panel-type display device such as a liquid crystal panel or an organic EL panel, and displays a moving image or a still image captured by the light detection apparatus 2002. The recording unit 2006 records the moving image or the still image captured by light detection apparatus 2002 in a recording medium such as a hard disk or a semiconductor memory.

The operation unit 2007 issues an operation command for various functions of the electronic equipment 2000 in response to an operation by the user. The power supply unit 2008 appropriately supplies various types of power to be used as operation power of the DSP circuit 2003, the frame memory 2004, the display unit 2005, the recording unit 2006, and the operation unit 2007 to these supply targets.

As described above, favorable images are expected to be acquired by using the above-described solid-state imaging apparatus 1 or the like as the light detection apparatus 2002.

### 6. APPLICATION EXAMPLE TO IN-VIVO INFORMATION ACQUISITION SYSTEM

The technology according to the present disclosure (the present technology) is applicable to various products. For example, the technology according to the present disclosure may be applied to an endoscopic surgery system.

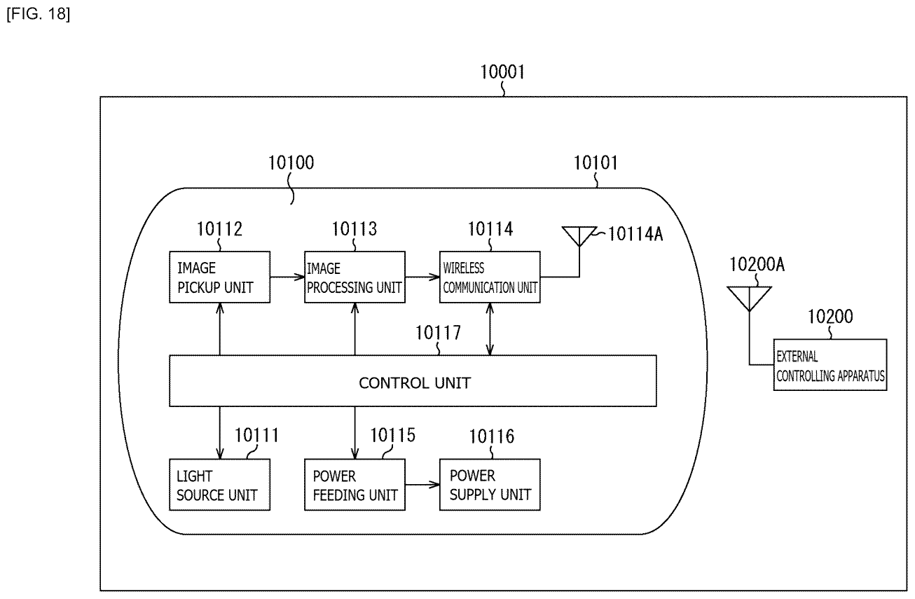

FIG. 18 is a block diagram depicting an example of a schematic configuration of an in-vivo information acquisition system of a patient using a capsule type endoscope, to which the technology according to an embodiment of the present disclosure (present technology) can be applied.

The in-vivo information acquisition system 10001 includes a capsule type endoscope 10100 and an external controlling apparatus 10200.

The capsule type endoscope 10100 is swallowed by a patient at the time of inspection. The capsule type endoscope 10100 has an image pickup function and a wireless communication function and successively picks up an image of the inside of an organ such as the stomach or an intestine (hereinafter referred to as in-vivo image) at predetermined intervals while it moves inside of the organ by peristaltic motion for a period of time until it is naturally discharged from the patient. Then, the capsule type endoscope 10100 successively transmits information of the in-vivo image to the external controlling apparatus 10200 outside the body by wireless transmission.

The external controlling apparatus 10200 integrally controls operation of the in-vivo information acquisition system 10001. Further, the external controlling apparatus 10200 receives information of an in-vivo image transmitted thereto from the capsule type endoscope 10100 and generates image data for displaying the in-vivo image on a display apparatus (not depicted) on the basis of the received information of the in-vivo image.

In the in-vivo information acquisition system 10001, an in-vivo image imaged a state of the inside of the body of a patient can be acquired at any time in this manner for a period of time until the capsule type endoscope 10100 is discharged after it is swallowed.

A configuration and functions of the capsule type endoscope 10100 and the external controlling apparatus 10200 are described in more detail below.

The capsule type endoscope 10100 includes a housing 10101 of the capsule type, in which a light source unit 10111, an image pickup unit 10112, an image processing unit 10113, a wireless communication unit 10114, a power feeding unit 10115, a power supply unit 10116 and a control unit 10117 are accommodated.

The light source unit 10111 includes a light source such as, for example, a light emitting diode (LED) and irradiates light on an image pickup field-of-view of the image pickup unit 10112.

The image pickup unit 10112 includes an image pickup element and an optical system including a plurality of lenses provided at a preceding stage to the image pickup element. Reflected light (hereinafter referred to as observation light) of light irradiated on a body tissue which is an observation target is condensed by the optical system and introduced into the image pickup element. In the image pickup unit 10112, the incident observation light is photoelectrically converted by the image pickup element, by which an image signal corresponding to the observation light is generated. The image signal generated by the image pickup unit 10112 is provided to the image processing unit 10113.

The image processing unit 10113 includes a processor such as a central processing unit (CPU) or a graphics processing unit (GPU) and performs various signal processes for an image signal generated by the image pickup unit 10112. The image processing unit 10113 provides the image signal for which the signal processes have been performed thereby as RAW data to the wireless communication unit 10114.

The wireless communication unit 10114 performs a predetermined process such as a modulation process for the image signal for which the signal processes have been performed by the image processing unit 10113 and transmits the resulting image signal to the external controlling apparatus 10200 through an antenna 10114A. Further, the wireless communication unit 10114 receives a control signal relating to driving control of the capsule type endoscope 10100 from the external controlling apparatus 10200 through the antenna 10114A. The wireless communication unit 10114 provides the control signal received from the external controlling apparatus 10200 to the control unit 10117.

The power feeding unit 10115 includes an antenna coil for power reception, a power regeneration circuit for regenerating electric power from current generated in the antenna coil, a voltage booster circuit and so forth. The power feeding unit 10115 generates electric power using the principle of non-contact charging.

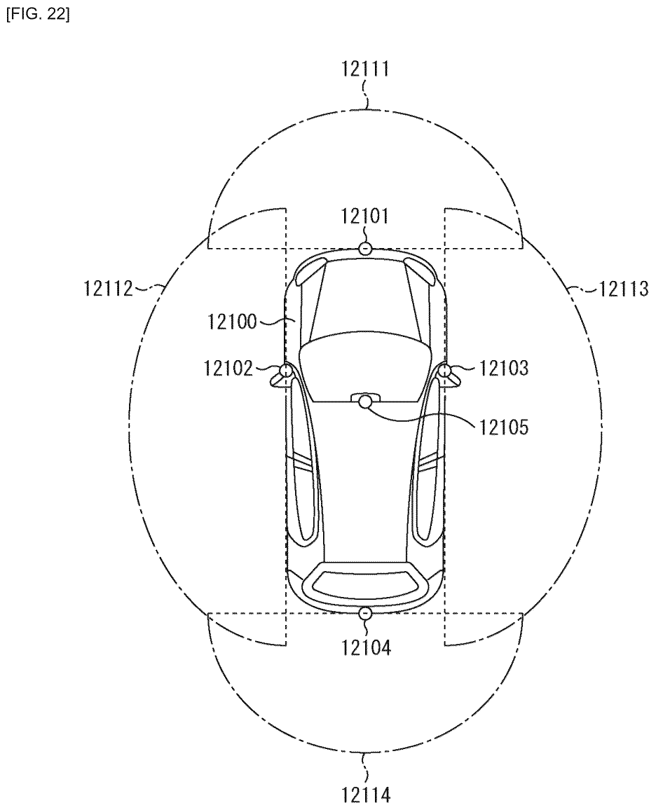

The power supply unit 10116 includes a secondary battery and stores electric power generated by the power feeding unit 10115. In FIG. 22, in order to avoid complicated illustration, an arrow mark indicative of a supply destination of electric power from the power supply unit 10116 and so forth are omitted. However, electric power stored in the power supply unit 10116 is supplied to and can be used to drive the light source unit 10111, the image pickup unit 10112, the image processing unit 10113, the wireless communication unit 10114 and the control unit 10117.

The control unit 10117 includes a processor such as a CPU and suitably controls driving of the light source unit 10111, the image pickup unit 10112, the image processing unit 10113, the wireless communication unit 10114 and the power feeding unit 10115 in accordance with a control signal transmitted thereto from the external controlling apparatus 10200.

The external controlling apparatus 10200 includes a processor such as a CPU or a GPU, a microcomputer, a control board or the like in which a processor and a storage element such as a memory are mixedly incorporated. The external controlling apparatus 10200 transmits a control signal to the control unit 10117 of the capsule type endoscope 10100 through an antenna 10200A to control operation of the capsule type endoscope 10100. In the capsule type endoscope 10100, an irradiation condition of light upon an observation target of the light source unit 10111 can be changed, for example, in accordance with a control signal from the external controlling apparatus 10200. Further, an image pickup condition (for example, a frame rate, an exposure value or the like of the image pickup unit 10112) can be changed in accordance with a control signal from the external controlling apparatus 10200. Further, the substance of processing by the image processing unit 10113 or a condition for transmitting an image signal from the wireless communication unit 10114 (for example, a transmission interval, a transmission image number or the like) may be changed in accordance with a control signal from the external controlling apparatus 10200.

Further, the external controlling apparatus 10200 performs various image processes for an image signal transmitted thereto from the capsule type endoscope 10100 to generate image data for displaying a picked up in-vivo image on the display apparatus. As the image processes, various signal processes can be performed such as, for example, a development process (demosaic process), an image quality improving process (bandwidth enhancement process, a super-resolution process, a noise reduction (NR) process and/or image stabilization process) and/or an enlargement process (electronic zooming process). The external controlling apparatus 10200 controls driving of the display apparatus to cause the display apparatus to display a picked up in-vivo image on the basis of generated image data. Alternatively, the external controlling apparatus 10200 may also control a recording apparatus (not depicted) to record generated image data or control a printing apparatus (not depicted) to output generated image data by printing.

The example of the in-vivo information acquisition system to which the technology according to the present disclosure is applicable has been described above. The technology according to the present disclosure may be applied to, for example, the image pickup unit 10112 of the configuration described above. This achieves a small-size device with high image detection accuracy.

### 8. APPLICATION EXAMPLE TO ENDOSCOPIC SURGERY SYSTEM

The technology according to the present disclosure (the present technology) is applicable to various products. For example, the technology according to the present disclosure may be applied to an endoscopic surgery system.

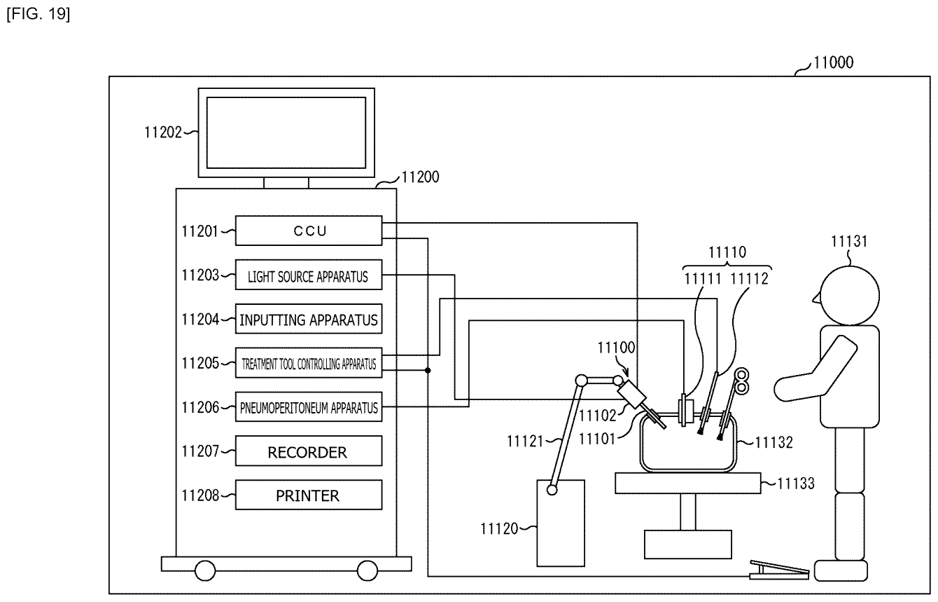

FIG. 19 is a view depicting an example of a schematic configuration of an endoscopic surgery system to which the technology according to an embodiment of the present disclosure (present technology) can be applied.

In FIG. 19, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

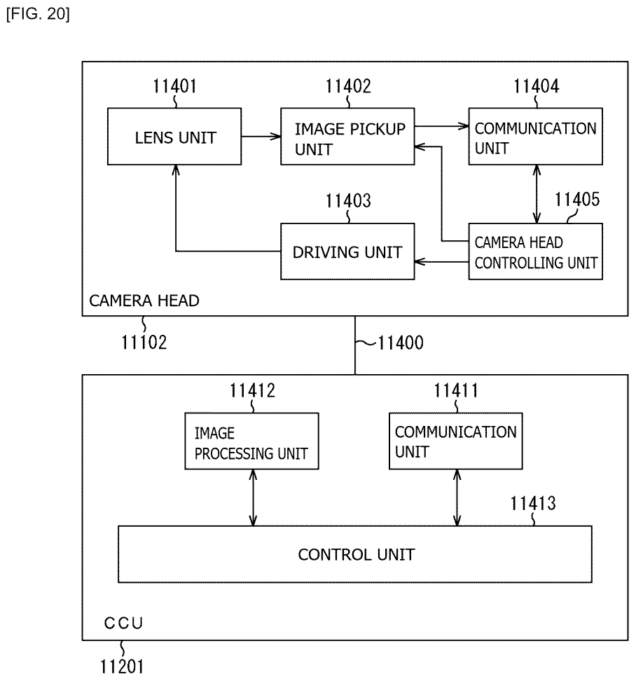

FIG. 20 is a block diagram depicting an example of a functional configuration of the camera head 11102 and the CCU 11201 depicted in FIG. 19.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R. G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The example of the endoscopic surgery system to which the technology according to the present disclosure is applicable has been described above. The technology according to the present disclosure may be applied to, for example, the image pickup unit 11402 of the camera head 11102 of the configuration described above. By applying the technology according to the present disclosure to the image pickup unit 10402, it is possible to obtain clearer images of surgical sites. This improves viewability of a surgical site for a surgeon.

It is to be noted that, although an endoscopic surgery system is described here as an example, the technology according to the present disclosure may be applied to other systems such as a microscopic surgery system, for example.

### 9. APPLICATION EXAMPLE TO MOBILE BODY

The technology according to the present disclosure (the present technology) is applicable to various products. For example, the technology according to the present disclosure may be embodied in the form of an apparatus to be mounted on a mobile body of any kind. Examples of the mobile body include an automobile, an electric vehicle, a hybrid electric vehicle, a motorcycle, a bicycle, a personal mobility device, an airplane, a drone, a vessel, and a robot.

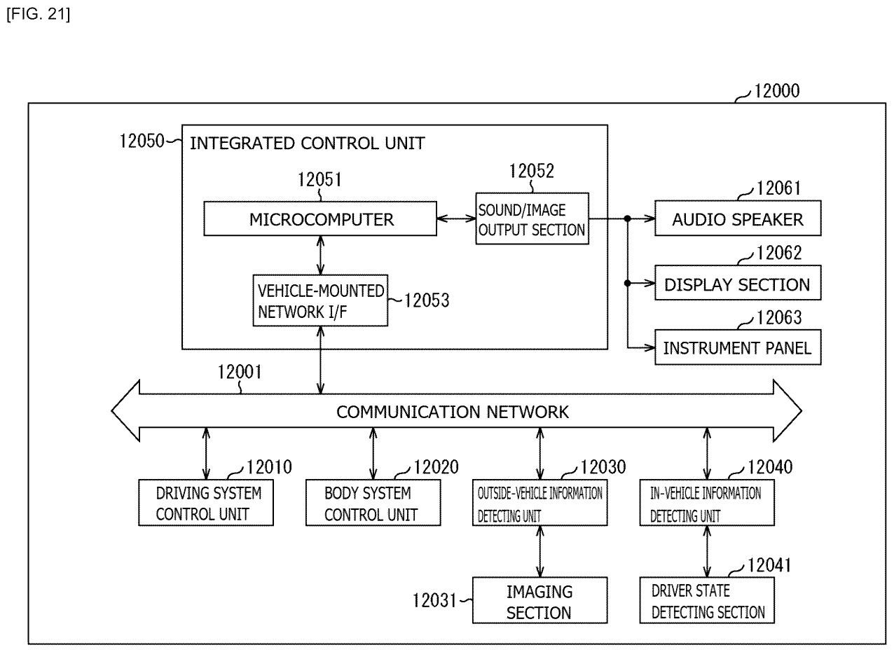

FIG. 21 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 21, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 21, an audio speaker 12061, a display section 12062, and an instrument panel 12063 are illustrated as the output device. The display section 12062 may, for example, include at least one of an on-board display and a head-up display.

FIG. 22 is a diagram depicting an example of the installation position of the imaging section 12031.

In FIG. 22, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 22 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The example of the vehicle control system to which the technology according to the present disclosure is applicable has been described above. The technology according to the present disclosure may be applied to, for example, the imaging section 12031 of the configuration described above. By applying the technology according to the present disclosure to the imaging section 12031, it is possible to obtain a captured image easier to see. This reduces the fatigue of a driver.

### 10. Other Modification Examples

Although the present disclosure has been described above with reference to some embodiments and modification examples, and application examples or exemplary applications thereof (hereinafter referred to as embodiments and the like), the present disclosure is not limited to the above-described embodiments and the like, and various modifications may be made. For example, the present disclosure is not limited to a backside illumination type image sensor, and is also applicable to a surface illumination type image sensor.

Moreover, the imaging apparatus of the present disclosure may be in the form of a module in which an imaging unit and a signal processing unit or an optical system are packaged together.

Furthermore, in the above-described embodiments and the like, description is given by giving the example of the solid-state imaging apparatus that converts the amount of entering light focused on the imaging plane through the optical lens system into the electric signal on the pixel-by-pixel basis and outputs the electric signal as the pixel signal, and the imaging element mounted thereon. However, the photoelectric conversion element of the present disclosure is not limited to such an imaging element. For example, it suffices for the photoelectric conversion element to detect and receive light from an object, generate electric charge corresponding to an amount of received light by photoelectric conversion, and accumulate the electric charge. A signal to be outputted may be a signal of image information or a signal of ranging information.

Moreover, in the above-described embodiments and the like, description is given by giving the example where the second photoelectric conversion unit 10 is an iTOF sensor. However, the present disclosure is not limited thereto. That is, the second photoelectric conversion unit is not limited to a photoelectric conversion unit that detects light having a wavelength in the infrared light range, but may be a photoelectric conversion unit that detects light having a wavelength in other wavelength ranges. In a case where the second photoelectric conversion unit 10 is not an iTOF sensor, only one transfer transistor (TG) may be provided.

Furthermore, in the above-described embodiments and the like, as the photoelectric conversion element of the present disclosure, the example of the imaging element is given in which the photoelectric conversion unit 10 including the photoelectric conversion region 12 and the first photoelectric conversion unit 20 including the photoelectric conversion layer 22 are stacked, with the intermediate layer 40 interposed therebetween. However, the present disclosure is not limited thereto. For example, the photoelectric conversion element of the present disclosure may have a structure in which two organic photoelectric conversion regions are stacked, or may have a structure in which two inorganic photoelectric conversion regions are stacked. Moreover, in the above-described embodiments and the like, the second photoelectric conversion unit 10 mainly detects light having a wavelength in the infrared light range to perform photoelectric conversion, and the first photoelectric conversion unit 20 mainly detects light having a wavelength in the visible light range to perform photoelectric conversion. However, the photoelectric conversion element of the present disclosure is not limited thereto. In the photoelectric conversion element of the present disclosure, the first photoelectric conversion unit and the second photoelectric conversion unit may be set to be sensitive to any wavelength range.

Moreover, the constituent materials of each of the constituent elements of the photoelectric conversion element of the present disclosure are not limited to the materials described in the above-described embodiments and the like. For example, in a case where the first photoelectric conversion unit or the second photoelectric conversion unit receives light in the visible light range and performs photoelectric conversion, the first photoelectric conversion unit or the second photoelectric conversion unit may include quantum dots.

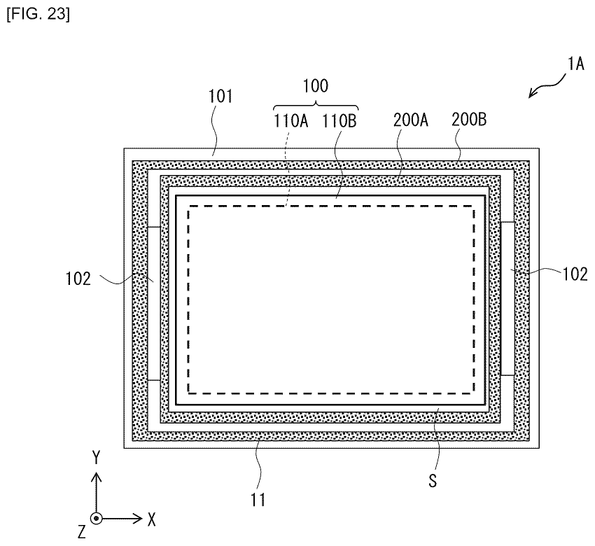

In addition, in the forgoing first embodiment, the single structural body 200 is provided in the peripheral unit 101 in an annular shape surrounding the pixel unit 100 in plan view. However, the present disclosure is not limited thereto. For example, as in a solid-state imaging apparatus 1A as a third modification example illustrated in FIG. 23, a structural body 200A and a structural body 200B may be provided in the peripheral unit 101. The structural body 200A is of an annular shape surrounding the pixel unit 100 in plan view. The structural body 200B is of an annular shape further surrounding the structural body 200A. In other words, multiple structural bodies may be multiplexedly disposed in the peripheral region to surround the effective region. In such a solid-state imaging apparatus 1A, it is possible to reduce the total amount of the multi-layer film 20Z to be removed in patterning the first photoelectric conversion unit 20, more than, for example, the solid-state imaging apparatus 1 in the first embodiment. This leads to further reduction in the residue to be generated. It is to be noted that, in the solid-state imaging apparatus 1A, the contact region 102 may be provided between, for example, the structural body 200A and the structural body 200B.

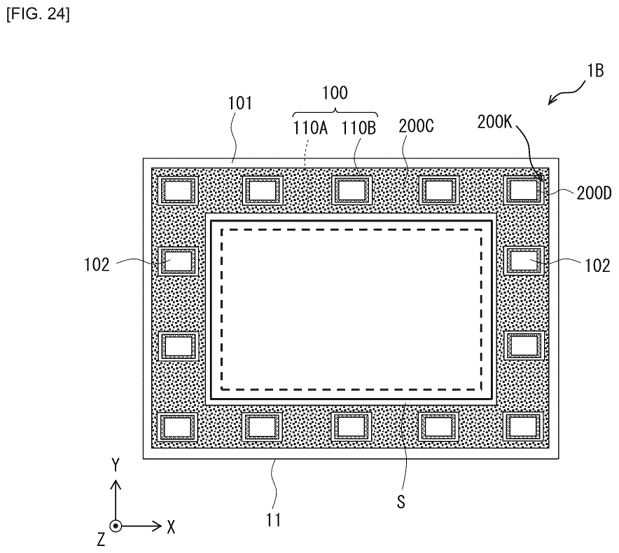

Moreover, for example, as in a solid-state imaging apparatus 1B as a fourth modification example illustrated in FIG. 24, one or more openings 200K may be provided inside an annular structural body 200C surrounding the pixel unit 100 in plan view. In this case, the contact region 102 may be provided in the openings 200K. Furthermore, an annular structural body 200D may be further provided inside each of the openings 200K. According to such a solid-state imaging apparatus 1B, it is possible to reduce the total amount of the multi-layer film 20Z to be removed in patterning the first photoelectric conversion unit 20, much more than, for example, the solid-state imaging apparatus 1 in the first embodiment. This leads to even further reduction in the residue to be generated.

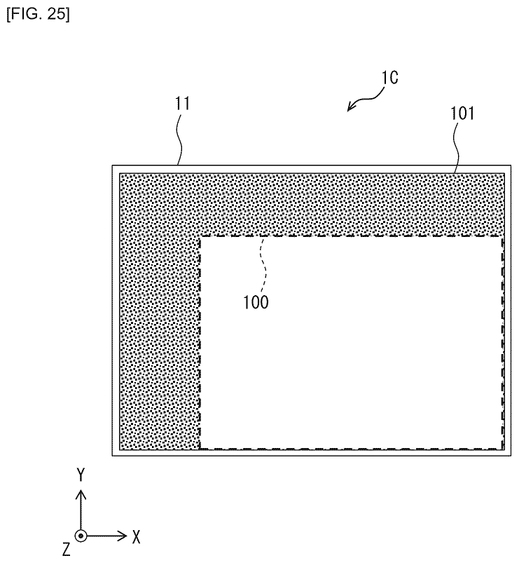

Moreover, in the forgoing first embodiment, the example is given where the peripheral region surrounds the effective region. However, the light detection apparatus of the present disclosure is not limited thereto. For example, as in a solid-state imaging apparatus 1C as a fifth modification example illustrated in FIG. 25, the peripheral unit 101 as the peripheral region may be disposed to face two sides of the pixel unit 100.

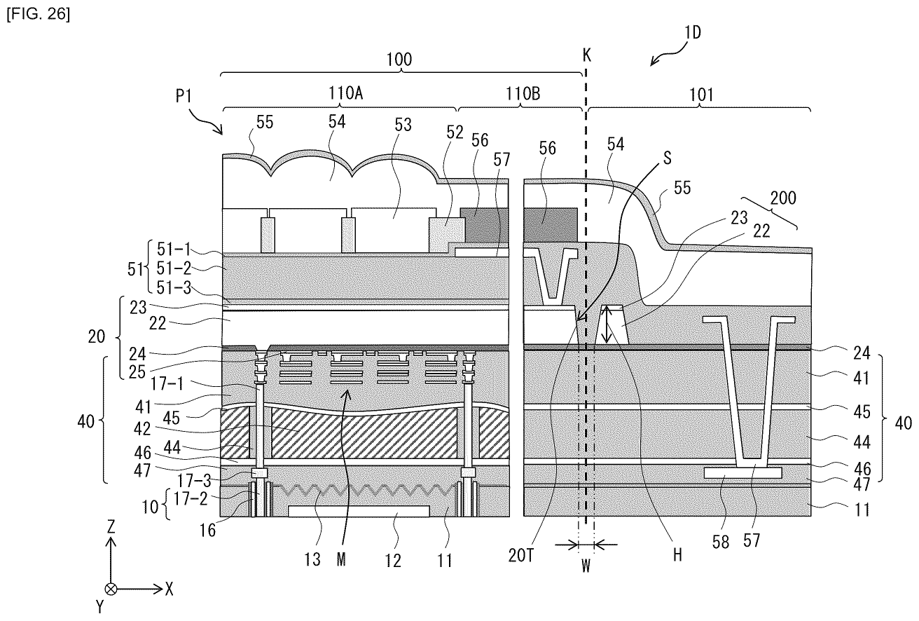

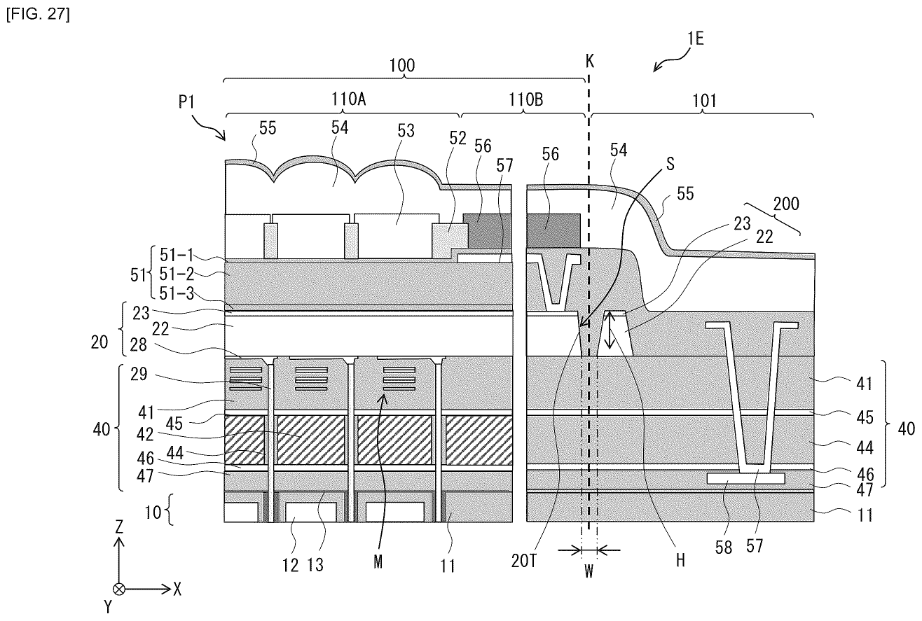

Moreover, in the forgoing first embodiment, the example is given where, as illustrated in FIG. 3, the first photoelectric conversion unit 20 includes the semiconductor layer 21. However, the present disclosure is not limited thereto. For example, as in a solid-state imaging apparatus 1D as a sixth modification example illustrated in FIG. 26, the first photoelectric conversion unit 20 may be devoid of the semiconductor layer 21. Moreover, as in a solid-state imaging apparatus 1E as a seventh modification example illustrated in FIG. 27, a mode may be possible in which the first photoelectric conversion unit 20 is devoid of the semiconductor layer 21 and the insulating layer 24, and the photoelectric conversion layer 22 is interposed between the upper electrode 23 and the lower electrode 28. To the lower electrode 28, an upper end of a through-electrode 29 is coupled. The through-electrode 29 extends in the thickness direction. A lower end of the through-electrode 29 is coupled to, for example, a charge holding part provided in the second photoelectric conversion unit 10.

According to the light detection apparatus of an embodiment of the present disclosure, as the first photoelectric conversion unit, a peripheral region part is provided in the peripheral region, in addition to an effective region part provided in the effective region. The effective region part and the peripheral region part are spaced apart. This suppresses the generation of residue near the edge face of the effective region part, in patterning the first photoelectric conversion unit by, for example, dry etching. As a result, it is possible to avoid a short circuit in the first photoelectric conversion unit, and obtain high performance.

It is to be noted that the effects described herein are mere examples. The present disclosure is thus not limited to the description and other effects may be obtained. Further, the present technology may have the following configurations.

(1) A light detection apparatus including:
an effective region that extends along a first plane and includes a first photoelectric conversion unit, the first photoelectric conversion unit detecting light in a first wavelength range to perform photoelectric conversion; and
a peripheral region provided adjacent to the effective region along the first plane, in which
the peripheral region includes a structural body spaced apart from and adjacent to the first photoelectric conversion unit, the structural body having a substantially same configuration as an entirety of the first photoelectric conversion unit or a portion of the first photoelectric conversion unit.

(2) The light detection apparatus according to (1) described above, in which
the first photoelectric conversion unit and the structural body each have a multi-layered structure in which a first electrode layer, a photoelectric conversion layer, and a second electrode layer are stacked in order in a first direction orthogonal to the first plane.

(3) The light detection apparatus according to (2) described above, in which
the first electrode layer, the second electrode layer, or both include a metal oxide.

(4) The light detection apparatus according to (3) described above, in which
the metal oxide includes at least one kind of In (indium), Zn (zinc), or Ga (gallium).

(5) The light detection apparatus according to any one of (1) to (4) described above, in which
a slit is provided between the first photoelectric conversion unit and the structural body, the slit being located at a boundary between the effective region and the peripheral region,
a ratio of a width of the slit along the first plane to a depth of the slit in a first direction orthogonal to the first plane is equal to or smaller than 1.

(6) The light detection apparatus according to (5) described above, in which the slit is filled with an insulating material.

(7) The light detection apparatus according to any one of (1) to (6) described above, further including:
a second photoelectric conversion unit superposed with the first photoelectric conversion unit in a first direction orthogonal to the first plane, the second photoelectric conversion unit detecting light in a second wavelength range to perform photoelectric conversion; and
an optical filter interposed between the first photoelectric conversion unit and the second photoelectric conversion unit, the optical filter allowing light in the second wavelength range to pass through more easily than light in the first wavelength range.

(8) The light detection apparatus according to any one of (1) to (7) described above, in which
the first photoelectric conversion unit and the structural body are provided at the same layer level.

(9) Electronic equipment including:
an optical unit;
a signal processing unit; and
a light detection apparatus, in which
the light detection apparatus includes
   an effective region that extends along a first plane and includes a first photoelectric conversion unit, the first photoelectric conversion unit detecting light in a first wavelength range to perform photoelectric conversion, and
   a peripheral region provided adjacent to the effective region along the first plane, and
the peripheral region includes a structural body spaced apart from and adjacent to the first photoelectric conversion unit, the structural body having a substantially same configuration as an entirety of the first photoelectric conversion unit or a portion of the first photoelectric conversion unit.

(10) A mobile body including
a light detection system including a light-emitting apparatus and a light detection apparatus, the light-emitting apparatus emitting irradiation light, in which
the light detection apparatus includes:
   an effective region that extends along a first plane and includes a first photoelectric conversion unit, the first photoelectric conversion unit detecting light in a first wavelength range among the irradiation light to perform photoelectric conversion; and
   a peripheral region provided adjacent to the effective region along the first surface, and
the peripheral region includes a structural body spaced apart from and adjacent to the first photoelectric conversion unit, the structural body having a substantially same configuration as an entirety of the first photoelectric conversion unit or a portion of the first photoelectric conversion unit.

(11) A light detection system including:
a light-emitting apparatus that emits infrared light; and
a light detection apparatus, in which
the light detection apparatus includes
   an effective region that extends along a first plane, and includes a first photoelectric conversion unit and a second photoelectric conversion unit, the first photoelectric conversion unit detecting visible light from outside to perform photoelectric conversion, and the second photoelectric conversion unit detecting the infrared light to perform photoelectric conversion, and
   a peripheral region provided adjacent to the effective region along the first plane,
the peripheral region includes a structural body spaced apart from and adjacent to the first photoelectric conversion unit, the structural body having a substantially same configuration as an entirety of the first photoelectric conversion unit or a portion of the first photoelectric conversion unit, and
the first photoelectric conversion unit and the second photoelectric conversion unit are superposed on each other in a first direction orthogonal to the first plane.

This application claims the benefit of Japanese Priority Patent Application JP2021-070934 filed with the Japan Patent Office on Apr. 20, 2021, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A light detection apparatus comprising:
an effective region that extends along a first plane and includes a first photoelectric conversion unit, the first photoelectric conversion unit detecting light in a first wavelength range to perform photoelectric conversion; and
a peripheral region provided adjacent to the effective region along the first plane, wherein
the peripheral region includes a structural body spaced apart from and adjacent to the first photoelectric conversion unit, the structural body having a substantially same configuration as an entirety of the first photoelectric conversion unit or a portion of the first photoelectric conversion unit.

2. The light detection apparatus according to claim 1, wherein the first photoelectric conversion unit and the structural body each have a multi-layered structure in which a first electrode layer, a photoelectric conversion layer, and a second electrode layer are stacked in order in a first direction orthogonal to the first plane.

3. The light detection apparatus according to claim 2, wherein the first electrode layer, the second electrode layer, or both include a metal oxide.

4. The light detection apparatus according to claim 3, wherein
the metal oxide includes at least one kind of In (indium), Zn (zinc), or Ga (gallium).

5. The light detection apparatus according to claim 1, wherein
a slit is provided between the first photoelectric conversion unit and the structural body, the slit being located at a boundary between the effective region and the peripheral region,
a ratio of a width of the slit along the first plane to a depth of the slit in a first direction orthogonal to the first plane is equal to or smaller than 1.

6. The light detection apparatus according to claim 5, wherein the slit is filled with an insulating material.

7. The light detection apparatus according to claim 1, further comprising:
a second photoelectric conversion unit superposed with the first photoelectric conversion unit in a first direction orthogonal to the first plane, the second photoelectric conversion unit detecting light in a second wavelength range to perform photoelectric conversion; and
an optical filter interposed between the first photoelectric conversion unit and the second photoelectric conversion unit, the optical filter allowing light in the second wavelength range to pass through more easily than light in the first wavelength range.

8. The light detection apparatus according to claim 1, wherein the first photoelectric conversion unit and the structural body are provided at a same layer level.

9. Electronic equipment comprising:
an optical unit;
a signal processing unit; and
a light detection apparatus, wherein
the light detection apparatus includes
an effective region that extends along a first plane and includes a first photoelectric conversion unit, the first photoelectric conversion unit detecting light in a first wavelength range to perform photoelectric conversion, and
a peripheral region provided adjacent to the effective region along the first plane, and
the peripheral region includes a structural body spaced apart from and adjacent to the first photoelectric conversion unit, the structural body having a substantially same configuration as an entirety of the first photoelectric conversion unit or a portion of the first photoelectric conversion unit.

10. A mobile body comprising
a light detection system including a light-emitting apparatus and a light detection apparatus, the light-emitting apparatus emitting irradiation light, wherein
the light detection apparatus includes:
an effective region that extends along a first plane and includes a first photoelectric conversion unit, the first photoelectric conversion unit detecting light in a first wavelength range among the irradiation light to perform photoelectric conversion; and
a peripheral region provided adjacent to the effective region along the first surface, and
the peripheral region includes a structural body spaced apart from and adjacent to the first photoelectric conversion unit, the structural body having a substantially same configuration as an entirety of the first photoelectric conversion unit or a portion of the first photoelectric conversion unit.

11. A light detection system comprising:
a light-emitting apparatus that emits infrared light; and
a light detection apparatus, wherein
the light detection apparatus includes
an effective region that extends along a first plane, and includes a first photoelectric conversion unit and a second photoelectric conversion unit, the first photoelectric conversion unit detecting visible light from outside to perform photoelectric conversion, and the second photoelectric conversion unit detecting the infrared light to perform photoelectric conversion, and
a peripheral region provided adjacent to the effective region along the first plane,
the peripheral region includes a structural body spaced apart from and adjacent to the first photoelectric conversion unit, the structural body having a substantially same configuration as an entirety of the first photoelectric conversion unit or a portion of the first photoelectric conversion unit, and
the first photoelectric conversion unit and the second photoelectric conversion unit are superposed on each other in a first direction orthogonal to the first plane.
